(19) United States
(12) Patent Application Publication
(10) Pub. No.: US 2026/0239776 A1
(43) Pub. Date: Aug. 13, 2026

(54) APPROACH TO ENHANCE OPTICAL ABSORPTION AND EMISSION RATES IN MOLECULAR AND SEMICONDUCTING SYSTEMS THROUGH MOMENTUM-MATCHING ENABLED BY THE CONFINEMENT OF PHOTONS

(71) Applicant: THE REGENTS OF THE UNIVERSITY OF CALIFORNIA, Oakland, CA (US)

(72) Inventors: Dmitry A. FISHMAN, Aliso Viejo, CA (US); Eric O. POTMA, Irvine, CA (US); Vartkess A. APKARIAN, Irvine, CA (US); Sergey S. KHARINTSEV, Tatarstan (RU)

(73) Assignee: THE REGENTS OF THE UNIVERSITY OF CALIFORNIA, Oakland, CA (US)

(21) Appl. No.: 19/474,910

(22) PCT Filed: Apr. 15, 2024
(86) PCT No.: PCT/US2024/024621

§ 371 Date: Oct. 13, 2025

Related U.S. Application Data
(60) Provisional application No. 63/459,437, filed on Apr. 14, 2023.
(60) Provisional application No. 63/612,230, filed on Dec. 19, 2023.

(51) Int. Cl. H10H 20/812; H10F 10/17; H10F 30/223; H10F 77/122; H10F 77/14; H10H 20/826

(52) U.S. Cl. CPC H10H 20/812; H10F 10/17; H10F 30/223; H10F 77/122; H10F 77/143; H10H 20/826

(57) ABSTRACT

The Heisenberg Uncertainty Principle reveals a fundamental link between a particle's position (Δx) and momentum (Δp) as Δx~ℏ/2·Δp., suggesting that photons confined to sub-nanometer scales can attain momentum comparable to electrons in solid materials. Our preliminary experiments confirm that photons can indeed achieve significant momentum. With considerable energy and momentum, photons can facilitate transitions in materials previously considered momentum forbidden, such as in indirect band gap semiconductors like silicon. Here, transitions require both photons (for energy) and lattice phonons (for momentum). Our findings show that a photon with high momentum can increase the optical transition rate in silicon by up to four orders of magnitude. This discovery opens new avenues for enhancing the efficiency of light detection, emission, and solar energy conversion in both indirect and direct semiconductor systems.

### CROSS-REFERENCE TO RELATED APPLICATIONS

This application claims the benefit of U.S. provisional application Ser. No. 63/459,437 filed Apr. 14, 2023, and U.S. provisional application Ser. No. 63/612,230 filed Dec. 19, 2023, the disclosures of which are hereby incorporated in their entirety by reference herein.

### TECHNICAL FIELD

In at least one aspect, the present invention is related to a method for increasing optical transitions in indirect semiconductors.

### BACKGROUND

Light absorption and emission in indirect bandgap materials are of keen interest in photovoltaics and optoelectronics.^{1,2} Silicon is a case in point, as it lies at the heart of modern electronics.³ An important challenge in photonics is to forge direct absorption and emission channels in Si and other materials throughout the visible and near-infrared range.^{4,5} Tunable visible photoluminescence (PL) in porous silicon (p-Si) was first observed in the early 1990s and has opened up exciting prospects for light-emitting silicon devices.⁶⁻¹⁰ Despite significant progress, the underlying mechanisms of PL in silicon continue to be widely debated.

A photon's energy and momentum, characterized by its angular frequency, are crucial in determining optical transitions in materials. A photon of angular frequency ω has an energy of E=ℏω and a momentum

$$p = \frac{ℏ ω}{c} = \frac{h}{{λ}_{0}}$$

in free space. The fundamental conservation laws dictate total energy and momentum of light and matter states to be conserved in optical transitions. For example, for light-induced transitions in atomic and molecular systems the conservation laws imply that the energy difference between material states must match the photon energy, while the momentum imparted by the photon is absorbed through the recoil of the atom or molecule. In semiconducting materials, on the other hand, the momentum difference between the electronic states can be orders of magnitude greater than the momentum carried by the photon. Thus, optically-allowed interband transitions, also known as direct transitions, are typically depicted as vertical arrows in the material's energy band diagram. Other transitions are considered optically forbidden due to the limited momentum supplied by the photon. This limiting effect is most notable in indirect semiconductors, as illustrated for the case of silicon in FIG. 1A. As shown in the energy band diagram, the lowest energetically allowed direct transition between the valence and conduction band in Si occurs at the Γ point and corresponds to an absorption energy of ~3.5 eV (~350 nm), well above the bandgap energy of the semiconductor. Below ~3.5 eV, direct transitions in Si are considered momentum-forbidden. However, these transitions are still possible, although they require assistance from lattice phonons to supply the needed momentum. This classifies such transitions as indirect, where the phonons are represented by arrows with a horizontal component along the k-axis in the energy band diagram (FIG. 1A).

The involvement of phonons significantly lowers the overall transition probability and reduces the absorption coefficient of Si throughout the visible and near-infrared spectral regions. Despite silicon's preeminence in microelectronics, its role in optoelectronic technologies has been relatively limited due to its unfavorable optical absorption and emission properties compared to direct semiconducting materials. Not surprisingly, many efforts have focused on improving the efficiency of optical transitions in Si.

The rate of optical transitions is given by Fermi's Golden Rule:

$$W = \frac{2 π}{ℏ} ρ {M}^{2} \qquad ( 1 )$$

in which the matrix element M contains the selection rules and energy and momentum conservation conditions, and ρ is the density of light-matter states. The latter may be decomposed into the product of optical density ρₒ and the joint density of occupied initial and final states of the matter, ρₘ. All efforts to optimize the transition rate of Si have to date focused on increasing the density of radiation states through light management,¹¹⁻¹⁸ aimed at efficient trapping of the incident radiation by texturing the surface using various fabrication techniques, from wet-chemistry etching to photolithography^{16, 19} to produce nanostructured1^{4,20}, porous^{21, 22} and black^{16, 17} silicon's. Indeed these efforts are aimed and succeed at converting Si into a black-body, namely converting its absorption probability to unity across the spectrum. However, they do so by trapping and concentrating the incident light to increase the interaction length and time and ensure thermodynamic equilibration.

Another strategy for improving silicon's optical properties would be to target the matrix element M itself. This can be realized by confining the photon wavefunction to a spatial extent of Δr, which in return is associated with an expansion of its momentum distribution to a width of Δp~2πℏ/Δr.

The matrix element contains the interaction Hamiltonian, A·∇, which in the case of a semiconductor acts on Bloch states |n, k [symbol] , and for the relevant interband transitions the matrix element can be put in the more transparent form:

$${M}^{2} = {( \frac{e {E}_{0} ℏ}{ω m c} )}^{2} \frac{N}{V} {〈 {u}_{{n}^{′}} \vert ∇ \vert {u}_{n} 〉}^{2} \int E ( r ) {e}^{i ( k - {k}^{′} ) r} dr δ [ ℏ ω - {E}_{nk , {n}^{′} {k}^{′}} ] \qquad ( 2 )$$

the energy conservation condition is given by the Dirac delta function, δ[ . . . ], obtained by integrating out the time dependence of the time harmonic field and states, the angle brackets is the transition dipole between the conduction and valence band in the Condon approximation (dropping the k-dependence within the unit cell), and the spatial integral is the momentum filter function. For a plane wave, E(r)=e^{iqr}, appropriate for a vacuum photon with momentum q=2π/λ₀, the momentum conservation condition of free space is given by δ[q−(k−k′)]. For a confined photon with a Gaussian spatial distribution,

$$E ( r ) = {e}^{- \frac{1}{2} {( \frac{r - {r}_{0}}{σ} )}^{2}} ,$$

a Gaussian momentum filter function σe^{-σ}^{²}^{(k-k′)}^{²} is obtained. Thus, in momentum space, the confined photon now carries a distribution of momenta, characterized by the variance σ.

The Gaussian weighted probability suggests that the momentum of a highly confined photon can be substantial. This also implies that, for highly confined photons, optical transitions previously labeled as indirect no longer require the involvement of additional particles (lattice phonons). Under such conditions, optical transitions are transformed to momentum-allowed, direct transitions and can be depicted as diagonal arrows in FIG. 1B. This transformation should be accompanied by a significant boost in the transition probability and the overall absorption coefficient of the indirect semiconductor across a broad spectral range (FIG. 1C).

To be effective, confinement on the scale of a few nm or smaller is required^{35, 36}. Ultimately, photons can be atomically confined, as has been demonstrated on atomically terminated asperities, such as the tips of scanning tunneling microscopes³⁷. Since the lattice constant of Si is a=0.54 nm, the first Brillouin zone spans π/a=5.79 nm⁻¹. While such confinement would cover the entirety of the zone, it would require only r=0.7 nm to introduce momentum comparable with Γ-X length³⁸. Thus, when confined to a Δr~0.3-5 nm scale, the photon momentum becomes comparable to the momentum differences associated with indirect transitions.^{35, 36, 39}

Accordingly, there is a need for devices that capitalize on the improved optical properties of semiconductor materials that take advantage of the principle of nanometer-scale photon confinement.

### SUMMARY

In at least one aspect, indirect-turned-direct optical transitions in semiconductors are facilitated by the broad expansion of photon momentum distribution when light is confined to length scales below 5 nm. The effect manifests itself in a significant increase in optical transition rates in silicon throughout the visible/near-infrared range. This effect holds the potential to strongly impact optical spectroscopies, light sensing, emission, and light-energy conversion.

In another aspect, a semiconductor device is provided. The semiconductor device includes an indirect bandgap semiconductor section that includes an indirect bandgap material and a plurality of nanostructures that are proximate to the surface of the indirect bandgap semiconductor section. Each nanostructure has an equivalent spherical diameter from 0.3 nm to 10 nm such that ultraviolet, visible, near-infrared, and mid-infrared light absorption and emission in the semiconductor section is increased through an expansion of photon-momentum inside and outside of the indirect bandgap semiconductor section as compared to a free photon.

In another aspect, a semiconductor device is provided. The semiconductor device or component thereof includes an indirect bandgap semiconductor section that includes an indirect bandgap material and a plurality of nanostructures that are proximate to a surface of the indirect bandgap semiconductor section. Advantageously, each nanostructure has an equivalent spherical diameter from 0.3 nm to 10 nm such that ultraviolet, visible, near-infrared, and mid-infrared light absorption and emission in the semiconductor section is increased through a mechanism of photon-electron momentum matching.

In another aspect, the indirect bandgap material is silicon.

In another aspect, a semiconductor device is provided. The semiconductor devices include a heterogeneous cross-linked semiconductor glass layer composed of a plurality of nano-sized inclusions of crystalline phase embedded in an amorphous semiconducting matrix. Characteristically, the nano-sized inclusions have an equivalent spherical diameter such that ultraviolet, visible, near-infrared, and mid-infrared light absorption and emission in the heterogeneous cross-linked semiconductor glass layer is increased through photon momentum expansion (as compared to a free photon).

In another aspect, a semiconductor device advantageously using photon-electron momentum matching is provided. The semiconductor device includes a substrate and a heterogeneous cross-linked silicon glass layer placed on the substrate. The heterogeneous cross-linked silicon glass layer includes a plurality of c-Si nanocrystals embedded in an amorphous silicon matrix. Characteristically, the c-Si nanocrystals have an equivalent spherical diameter such that ultraviolet, visible, near-infrared, and mid-infrared light absorption and emission in the heterogeneous cross-linked silicon glass layer is increased through photon-electron momentum matching. Alternatively stated, the c-Si nanocrystals have an equivalent spherical diameter such that ultraviolet, visible, near-infrared, and mid-infrared light absorption and emission in the heterogeneous cross-linked in semiconductor glass layer is increased through photon momentum expansion (as compared to a free photon).

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

For a further understanding of the nature, objects, and advantages of the present disclosure, reference should be had to the following detailed description, read in conjunction with the following drawings, wherein like reference numerals denote like elements and wherein:

FIGS. 1a, 1b, and 1c. (a) Energy-momentum diagram for optical transition in pure Si and free space photons. The arrows indicate direct (blue arrow, ~k=0) and indirect optical transitions (red and velvet arrows, kₚₕₒₙₒₙ>0). (b) Energy-momentum diagram showing optical transitions enabled by the momenta of photons confined to a spatial scale of Δr, without the need of lattice phonons. Both diagrams (a) and (b) depict optical transitions near the Γ point, excluding other momentum-enabled transitions at various points across the Brillouin zone. (c) Absorption spectrum of Si⁴⁰ and direct bandgap semiconductors as CuInSe2⁴¹ and InP^{42,43}. Dashed curve and shaded region indicate enhancement of absorption coefficient across a broad spectral range due to momentum-enabled transitions.

FIG. 2a. Schematic of a semiconductor device having metal/semiconductor/insulator nanostructures that enhance optical transition.

FIG. 2b. Schematic of a semiconductor device having physical structures that enhance optical absorption.

FIG. 2c. Schematic of a semiconductor device having embedded physical structures that enhance optical absorption.

FIG. 2d. Schematics of a semiconductor device having c-Si nanocrystals embedded in an amorphous silicon matrix.

FIGS. 3a and 3b. Schematics of a semiconductor device having c-Si nanocrystals embedded in an amorphous silicon matrix.

FIGS. 4a, 4b, 4c, 4d, 4e, 4f, 4g, 4h, 4i, and 4j. Experimental configuration when a Si AFM cantilever is placed over (a) bare glass and (b) a 50 nm gold film with surface roughness of h₀=1.7 nm±0.65 nm. Panels (c) and (d) show Si Raman spectra as a function of laser intensity for either bare glass or the smooth gold film. The insets indicate Raman spectra along the dashed straight line. (e-h) SEM images of an intact AFM cantilever with the tip apex (inset) and the apex after illumination for different substrates. (i) AFM image of the 50 nm thick Au film and its (j) surface roughness height distribution histogram centered at h₀=1.7 nm (σ_{FWHM}=1.3 nm).

FIGS. 5a, 5b, and 5c. Sensing of tip apex temperature through Raman thermometry and cantilever phase evolution. (a) AFM topography cross-section of preliminarily identified gold structures. (b) Raman spectrum evolution and (c) phase dynamic as a function of input light intensity. The data clearly show Si cantilever temperature is reversed proportional to the structure size.

FIGS. 6a, 6b, 6c, 6d, and 6e. Experiments on Si wafers with deposited Au structures. (a) Height distribution histogram of a single layer of Au nanoparticles of height ~1.3 nm and ~2.2 nm. (b) Visible/near-infrared reflection spectra of clean and coated Si wafers. Smaller particles provide broader momenta distribution, hence resulting in stronger and spectrally broader absorption enhancement. (c, d) AFM image and height distribution histogram of Au-coated surface Si wafer after sputtering. (e) Photocurrent input power density dependence measured from Si photodiode with clean and coated photosensitive layer. The data shows 30% increase in detector responsivity for 2.2±0.5 nm Au structures.

FIGS. 7a, 7b, 7c, 7d, 7e, and 7f. (a) An artistic representation of the light-assisted formation of cross-linked semiconductor glass stripes on a-Si film. (b) Schematic representation of temperature-dependent formation of homogenous cross-linked glass (through sintering) and heterogeneous cross-linked glass (through crystallization). (c) AFM topography and (d) cross-section of an array series. By varying exposure time (writing speed), one can form areas with different degree of crystallinity and a narrow distribution of sizes within light affected zones (e) and heat-only affected zones (f).

FIGS. 8a, 8b, 8c, and 8d. (a) Raman spectra of a-Si (light blue), c-Si (pink) using 532 nm excitation and silicon glass at LAZ (0.5 μm/s) using 532 nm (green) and 633 nm (orange) excitation wavelengths, (b) Decomposition of Raman spectrum at LAZ written at 0.5 μm/s. (c) and (d) The h-ERS shift vs size for LAZ and HAZ using 532 nm and 633 nm excitation wavelengths.

FIGS. 9a and 9b. (a) The l-ERS linewidth at LAZ (Urbach energy) as a function of structure size. The inset shows a schematic representation of the Urbach bridge following Mott and Davis's concept. 49,55 (b) A Conceptual visual representation of direct and indirect optical transitions for understanding the origins of l-ERS and h-ERS.

FIG. 10. A 1D array of straight lines fabricated on a-Si film using different laser scanning speeds: VRS maps (a-Si (a) and c-Si (b)) and ERS maps (1-ERS (c) and (d), (e) here). A light-structured cross-linked network on a-Si film at different pitch: VRS maps (a-Si (f), c-Si (g) and a boson peak (h)) and ERS maps ((i), (j) h-ERS).

### DETAILED DESCRIPTION

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

It should also be appreciated that integer ranges explicitly include all intervening integers. For example, the integer range 1-10 explicitly includes 1, 2, 3, 4, 5, 6, 7, 8, 9, and 10. Similarly, the range 1 to 100 includes 1, 2, 3, 4 . . . 97, 98, 99, 100. Similarly, when any range is called for, intervening numbers that are increments of the difference between the upper limit and the lower limit divided by 10 can be taken as alternative upper or lower limits. For example, if the range is 1.1. to 2.1 the following numbers 1.2, 1.3, 1.4, 1.5, 1.6, 1.7, 1.8, 1.9, and 2.0 can be selected as lower or upper limits. In the specific examples set forth herein, concentrations, temperature, and reaction conditions (e.g. pressure, pH, etc.) can be practiced with plus or minus 50 percent of the values indicated rounded to three significant figures. In a refinement, concentrations, temperature, and reaction conditions (e.g., pressure, pH, etc.) can be practiced with plus or minus 30 percent of the values indicated rounded to three significant figures of the value provided in the examples. In another refinement, concentrations, temperature, and reaction conditions (e.g., pH, etc.) can be practiced with plus or minus 10 percent of the values indicated rounded to three significant figures of the value provided in the examples.

In the examples set forth herein, concentrations, temperature, and reaction conditions (e.g., pressure, pH, flow rates, sputtering conditions, etc.) can be practiced with plus or minus 50 percent of the values indicated rounded to or truncated to two significant figures of the value provided in the examples. In a refinement, concentrations, temperature, and reaction conditions (e.g., pressure, pH, flow rates, etc.) can be practiced with plus or minus 30 percent of the values indicated rounded to or truncated to two significant figures of the value provided in the examples. In another refinement, concentrations, temperature, and reaction conditions (e.g., pressure, pH, flow rates, etc.) can be practiced with plus or minus 10 percent of the values indicated rounded to or truncated to two significant figures of the value provided in the examples.

Throughout this application, where publications are referenced, the disclosures of these publications in their entireties are hereby incorporated by reference into this application to more fully describe the state of the art to which this invention pertains.

The term “equivalent spherical diameter” means the diameter of a sphere having the same volume as the nanoparticle.

The term “root mean square roughness” means the square root of the mean squared deviation of the surface height from the mean plane.

The term “mean plane” means the plane that minimizes the sum of the squared deviations of the surface height from the plane.

The prefix “nano” means that the object including the prefix has at least one dimension less than or equal to 100 nm.

The term “visible light” means the portion of the electromagnetic spectrum from approximately 400 to 700 nanometers.

The term “infrared light” means the portion of the electromagnetic spectrum from approximately 700 to 2500 nanometers.

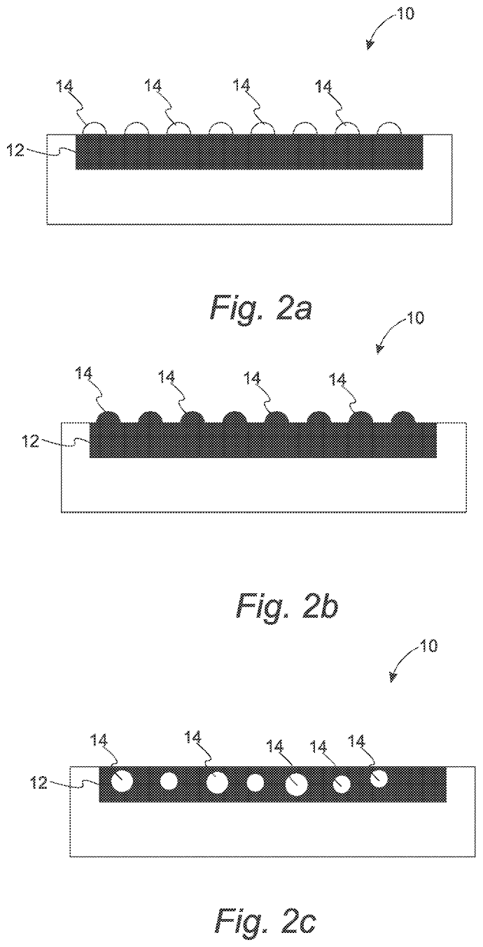

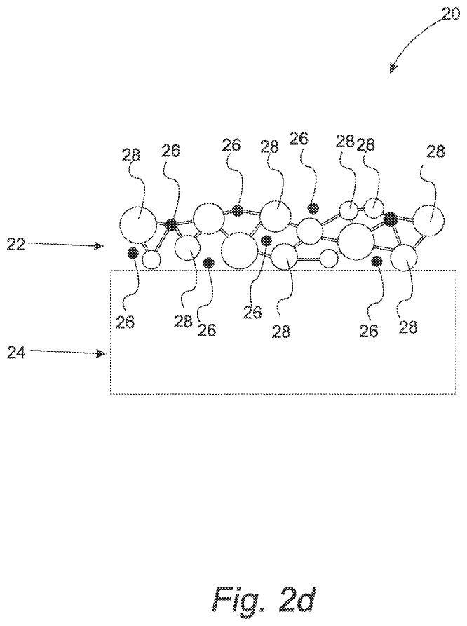

Referring to FIGS. 2a, 2b, and 2c, schematics of a semiconductor device with enhanced light absorption are provided. Semiconductor device 10 includes a semiconductor section 12 that includes an indirect bandgap material. A plurality of nanostructures 14 is proximate to the surface of the indirect bandgap semiconductor section 12. Characteristically, each nanostructure has an equivalent spherical diameter of at most 10 nm such that visible and near-infrared light absorption and/or emission in the indirect bandgap semiconductor section is increased compared to light absorption and/or emission when the plurality of nanostructures is not present. Advantageously, light absorption is increased by optical transitions enabled by the momentum of confined photons.

In another aspect, each nanostructure has an equivalent spherical diameter from 0.3 nm to 10 nm such that ultraviolet, visible, near-infrared, and mid-infrared light absorption and emission in the semiconductor section is increased through an expansion of photon-momentum. In a refinement, this expansion of photon-momentum is inside and outside of the material. In this context, “outside and inside of the material” means within the bulk material and in near proximity to the surface. Moreover, expansion of photon-momentum means increasing or broadening of the photon momentum distribution. The increase in momentum is relative to a free photon (i.e., a far-field photon), which has negligible, nearly zero momentum. In a refinement, the far field region of an electromagnetic source (like a light-emitting device) is the region where the distance from the source is much greater than the wavelength of the emitted light. In this region, the wavefronts of the light are essentially planar, and the angular spread of the light can be described by simple geometrical optics. For example, if we consider a far-field photon of 600 nm (i.e., its wavelength), its momentum is small. However, if the same photon is confined to 1 nm its momentum increases by 600 times.

In another aspect, the indirect bandgap semiconductor section is a heterogeneous cross-linked silicon glass layer, and the plurality of nanostructures are a plurality of c-Si nanocrystals embedded in an amorphous silicon matrix. In a refinement, the c-Si nanocrystals have an equivalent spherical diameter such that ultraviolet, visible, near-infrared, and mid-infrared light absorption and emission in the heterogeneous cross-linked silicon glass layer is increased through photon-electron momentum matching compared to light absorption and emission when the plurality of c-Si nanocrystals is not present.

In another aspect, the plurality of nanostructures includes physical structures that are fabricated by chemical etching, focused ion milling, electron beam lithography, photolithography, Bosch milling, or machined into the indirect bandgap semiconductor section.

In another aspect as depicted in FIG. 2a, the plurality of nanostructures includes metal nanoparticles or semimetal nanoparticles. In one refinement, the plurality of nanostructures is arranged as an array over the surface of the indirect bandgap semiconductor section. In another refinement, the plurality of nanostructures is a metallic grid, arrangement, specific design, and/or periodic structure within or contacting indirect bandgap semiconductor section volume and/or contacting the surface of the indirect bandgap semiconductor section.

In another aspect as depicted in FIG. 2b, the plurality of nanostructures includes structures defined by the surface of the indirect bandgap semiconductor section. In a refinement, the plurality of nanostructures includes physical structures that are etched or machined into the indirect bandgap semiconductor section.

In another aspect as depicted in FIG. 2c, the plurality of nanostructures includes structures embedded in the indirect bandgap semiconductor section. For instance, these nanostructures can be quantum dots, nanowires, or nanorods strategically positioned within the semiconductor material. The purpose of these structures is to capture and confine the incident photon to the nanometer scale inside the semiconductor host material. The integration of nanostructures into the indirect bandgap semiconductor allows for the tailoring of the material's characteristics to suit specific applications, opening new avenues for advancements in semiconductor technology.

In various aspects, the semiconductor device is included in a range of applications: a photodiode, a photovoltaic cell, an optical sensor, an imaging array, a nano printing device, a computational metamaterial device, a nano heater device for single molecule and supramolecular systems as well as polymerase chain reactions, a catalysis device, a water desalination device, and an optical data encrypting device. Each of these applications showcases the versatility and wide-ranging utility of the semiconductor device in advancing technology across different fields.

In another aspect, the plurality of nanostructures is defined by a surface roughness of a metallic layer disposed over the indirect bandgap semiconductor section, the surface roughness having a root mean square roughness less than about 10 nm. In a refinement, the root mean square roughness less than about 5 nm. In a further refinement, the root mean square roughness greater than about 0.1 nm, 0.5 nm, 0.8 nm, or 1 nm.

In another aspect, the equivalent spherical diameter is at most 5 nm. In a further refinement, the equivalent spherical diameter is at most 3 nm. In a further refinement, the equivalent spherical diameter is at least 1 nm. In some refinements, the equivalent spherical diameter is at most 10 nm, 9 nm, 8 nm, 7 nm, 6 nm, 5 nm, 4 nm, or 3 nm, and at least 0.1 nm, 0.5 nm, 0.7 nm, 1 nm, or 2 nm.

In another aspect, adjacent nanostructures are separated by a distance of at least the average equivalent spherical diameter of the plurality of nanostructures. In a refinement, adjacent nanostructures are separated by at least 5 nm. In some refinements, adjacent nanostructures are separated by at least 2 nm, 3 nm, 4 nm, 5 nm, or 6 nm. In further refinements, adjacent nanostructures are separated by at most 20 nm, 15 nm, 10 nm, 8 nm, or 6 nm.

The methodology described herein can be used for virtually any indirect bandgap semiconductor. Examples of such indirect bandgap semiconductor sections include an indirect and/or direct bandgap material selected from the group consisting of silicon (Si), germanium (Ge), germanium (Ge), InGaAsP modifications, gallium Arsenide (GaAs), indium phosphide (InP), cadmium sulfide (CdS), cadmium telluride (CdTe), zinc selenide (ZnSe), zinc telluride (ZnTe), indium antimonide (InSb), lead sulfide (PbS), zinc oxide (ZnO) and combinations thereof. In this regard, silicon is found to be particularly useful.

In another aspect, the semiconductor device described of FIGS. 2a, 2b, and 2c and in particular, semiconductor section 12 can be advantageously included in optical devices such as photodiodes, photovoltaic cells, optical sensors, and imaging arrays.

Referring to FIG. 2d, a schematic of a semiconductor device with enhanced light absorption is provided. In a refinement, semiconductor device 20 includes a heterogeneous cross-linked semiconductor glass layer 22 that includes a heterogeneous cross-linked semiconductor glass. Semiconductor glasses, also known as amorphous semiconductors, are materials that have disordered structures, unlike the crystalline structure of typical semiconductors like silicon or gallium arsenide. These materials can exhibit semiconducting properties, making them useful in various electronic and optical applications. Examples of semiconductor glasses include but are not limited to amorphous silicon (a-Si) and chalcogenide-based heterogeneous glasses. In a refinement, cross-linked semiconductor glass layer 22 is composed of silicon.

In another aspect, a heterogeneous cross-linked semiconductor glass layer 22 is disposed over an optional substrate 24 (e.g., heterogeneous cross-linked silicon glass layer). The substrate can be any suitable material such as glass or a wafer. In a refinement, heterogeneous cross-linked semiconductor glass layer 22 has a thickness from about 100 nm to 1000 nm. The heterogeneous cross-linked semiconductor glass layer 22 includes a plurality of nano-sized inclusions 26 embedded in an amorphous matrix 28. In a refinement, nano-sized inclusions 26 can include nanocrystals of the material forming the heterogeneous cross-linked semiconductor glass layer or another material, gold, and other nanostructures. In a refinement when the glass is composed of silicon, the nano-sized inclusions 26 can be c-Si (i.e., crystalline silicon) nanocrystals. In a refinement, nanostructure inclusions 26 have an equivalent spherical diameter such that ultraviolet, visible, near-infrared, and mid-infrared light absorption and emission in the heterogeneous cross-linked silicon glass layer 22 is increased through the mechanism of photon-electron momentum matching as described above. Characteristically, the heterogeneous cross-linked semiconductor glass layer 22 is composed of a material that represents an intermediate state between the amorphous and crystalline phases, characterized by a narrow distribution of structure sizes.

In a variation, heterogeneous cross-linked semiconductor glass layer 22 is formed by annealing amorphous silicon (a-Si) with a continuous wave (cw) laser.

In a variation, the equivalent spherical diameter of the nano-sized inclusion (e.g., c-Si nanocrystals) is from 0.3 nm to 10 nm. In a refinement, the equivalent spherical diameter is at most 5 nm. In a further refinement, the equivalent spherical diameter is at most 3 nm. In a further refinement, the equivalent spherical diameter is at least 1 nm.

In another variation, adjacent nano-sized inclusions 26 (e.g., c-Si nanocrystals) are separated by a distance of at least an average equivalent spherical diameter of the plurality of nanostructures. In a refinement, adjacent nano-sized inclusions 26 (e.g., c-Si nanocrystals) are separated by at least 3 nm. In a further refinement, adjacent nano-sized inclusions 26 (e.g., c-Si nanocrystals) are separated by at least 0.3 nm. In some refinements, adjacent nano-sized inclusions 26 (e.g., c-Si nanocrystals) are separated by at least 3 nm, 4 nm, 5 nm, or 5 nm and at most 15 nm, 12 nm, 10 nm, or 7 nm

In another variation, the plurality of nano-sized inclusions 26 (e.g., c-Si nanocrystals) induce a surface roughness over heterogeneous cross-linked silicon glass layer 22. In a refinement, the root mean square roughness is less than about 5 nm. In a further refinement, the root mean square roughness is greater than about 0.1 nm, 0.5 nm, 0.8 nm, or 1 nm and less than about 6 nm, 5 nm, 3 nm, or 2 nm.

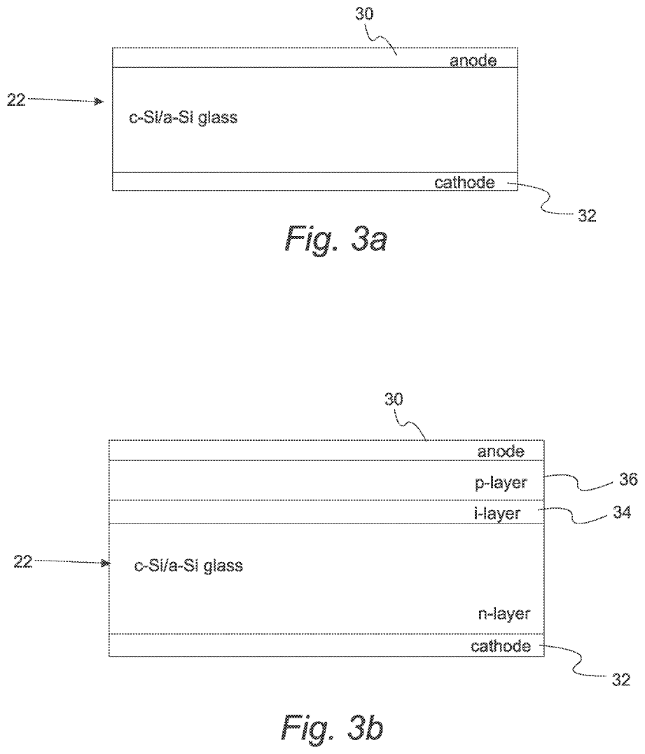

In another aspect, FIG. 3a provides a schematic of a semiconductor device incorporating heterogeneous cross-linked semiconductor glass layer 22 (e.g., a heterogeneous cross-linked silicon glass layer) between an anode 30 and cathode 32.

In another aspect, a photodiode includes the semiconductor device 20 and/or heterogeneous cross-linked semiconductor glass layer 22 (e.g., a heterogeneous cross-linked silicon glass layer).

In another aspect, a photovoltaic cell includes the semiconductor device 20 and/or heterogeneous cross-linked semiconductor glass layer 22 (e.g., a heterogeneous cross-linked silicon glass layer). For example, FIG. 3b provides a schematic of a semiconductor device incorporating heterogeneous cross-linked silicon glass layer 22 in a pin junction that includes cross-linked semiconductor glass layer 22 (e.g., the n-layer), intrinsic layer 34, and p-layer 36. The pin junction is disposed between anode 30 and cathode 32.

In another aspect, an optical sensor includes the semiconductor device 20 or heterogeneous cross-linked semiconductor glass layer 22 (e.g., a heterogeneous cross-linked silicon glass layer).

In another aspect, an imaging array includes the semiconductor device 20 or heterogeneous cross-linked semiconductor glass layer 22 (e.g., a heterogeneous cross-linked silicon glass layer).

In another aspect, a nanoprinting device includes semiconductor device 20 or heterogeneous cross-linked semiconductor glass layer 22 (e.g., a heterogeneous cross-linked silicon glass layer).

In another aspect, a computational metamaterial device includes the semiconductor device 20 or heterogeneous cross-linked semiconductor glass layer 22 (e.g., heterogeneous cross-linked silicon glass layer).

In another aspect, a nano heater device for single molecule and supramolecular system, polymerase chain reaction includes the semiconductor device 20 and/or heterogeneous cross-linked semiconductor glass layer 22 (e.g., a heterogeneous cross-linked silicon glass layer).

In another aspect, a catalysis device includes the semiconductor device 20 or heterogeneous cross-linked semiconductor glass layer 22 (e.g., a heterogeneous cross-linked silicon glass layer).

In another aspect, a water desalination device includes the semiconductor device 20 or heterogeneous cross-linked semiconductor glass layer 22 (e.g., a heterogeneous cross-linked silicon glass layer).

In another aspect, an optical data encrypting device includes the semiconductor device 20 or heterogeneous cross-linked semiconductor glass layer 22 (e.g., a heterogeneous cross-linked silicon glass layer).

Additional details of the embodiments set forth above are found in S. S. Kharintsev et al, Photon-Momentum-Enabled Electronic Raman Scattering in Silicon Glass, ACS Nano 2024, 18, 13, 9557-9565, Publication Date: Mar. 4, 2024, https://doi.org/10.1021/acsnano.3c12666 and its supplemental information; the entire disclosure of which is hereby incorporated by reference in its entirety.

The following examples illustrate the various embodiments of the present invention. Those skilled in the art will recognize many variations that are within the spirit of the present invention and scope of the claims.

### 1. Molecular and Semiconducting Systems Exhibiting Momentum Expansion Enabled by the Confinement of Photons

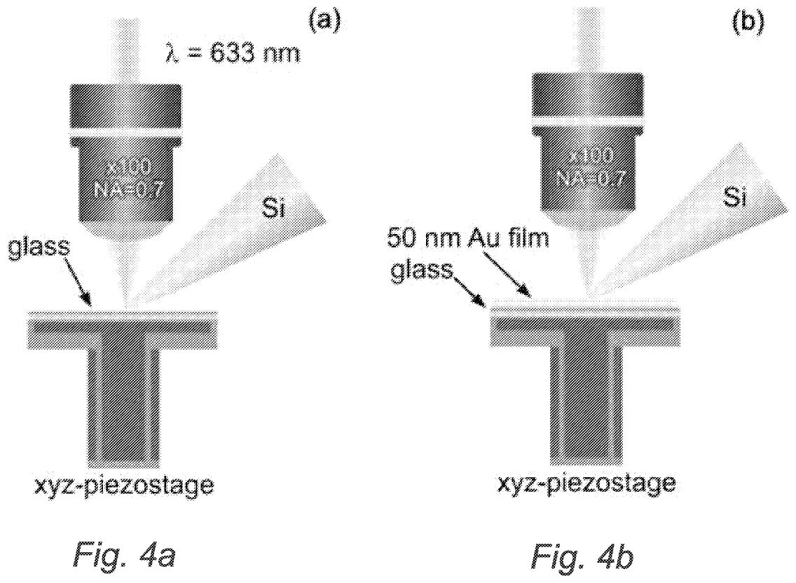

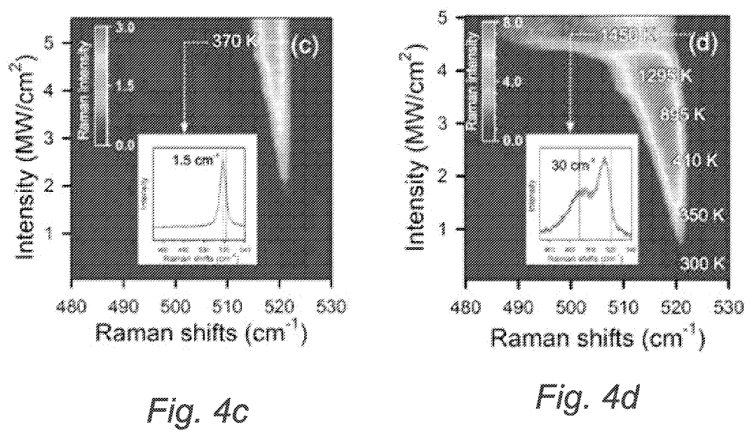

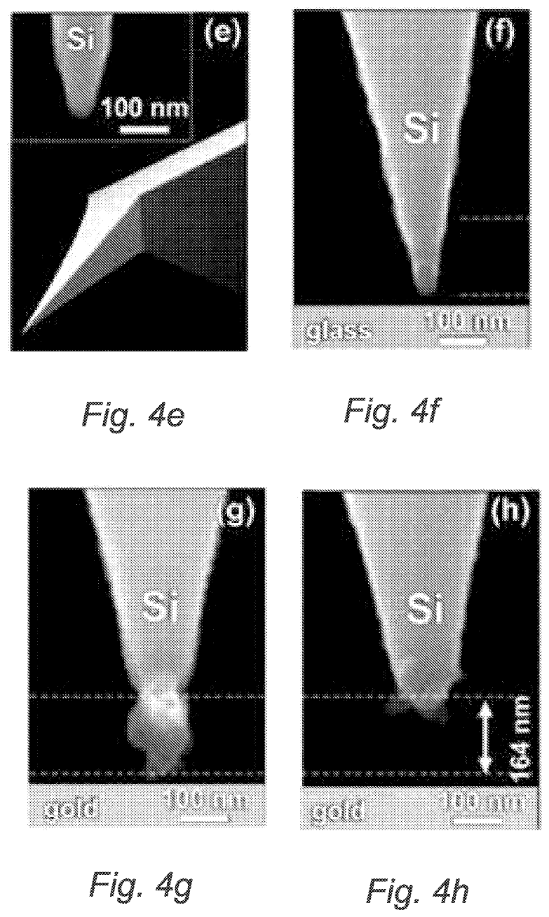

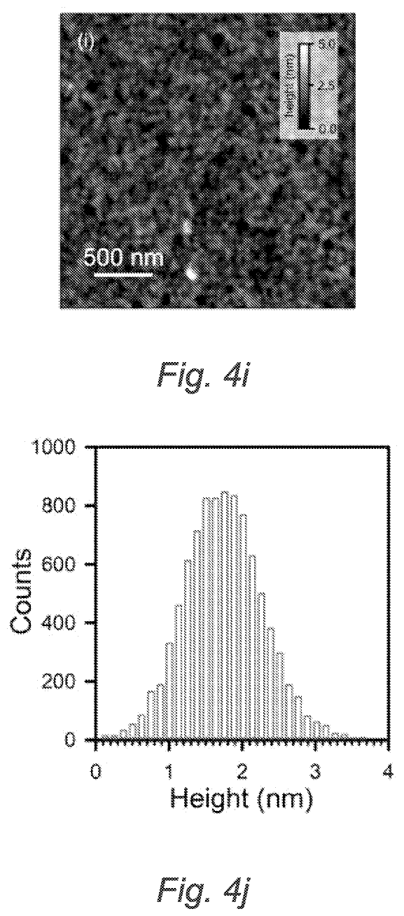

The experiments set forth below demonstrate enhanced absorption in Si due to an expanded distribution of photon momenta. For this purpose, the efficiency of optical absorption in an atomically sharp Si tip under conditions where such a momentum expansion can be expected is examined. In order to determine the optical absorption efficiency, the heating of the tip is monitored, using the temperature dependent Raman spectrum of silicon as the measured quantity of interest. The experiment consists of a tip-enhanced Raman scattering (TERS) microscope, equipped with a Si AFM cantilever that is oscillating in semi-contact mode over a planar substrate. The tip is illuminated with a focused linearly polarized beam derived from a continuous laser at 633 nm (FIGS. 4a and 4b). In these measurements, the intensity, spectral position and shape of the c-Si line (521 cm⁻¹) are monitored. The temperature dependence of this Raman mode makes it possible to estimate the absolute lattice temperature through Raman thermometry^{36,44}.

FIG. 4c shows the evolution of the Si Raman spectrum when the tip is placed over a bare glass substrate and the laser intensity is gradually increased. A small linear shift of the peak position towards lower energy with increasing laser intensity is observed, which is attributed to heating of the tip due to light absorption. More careful analysis of the spectral line at 5 MW/cm² reveals a shift of 1.5 cm⁻¹ (inset of FIG. 4c, see Methods), corresponding to a rise of ΔT~70 K above ambient room temperature. These temperatures are well below the melting point of Si, thus retaining the structural integrity of the tip, as evidenced by post-experiment SEM imaging (FIG. 4f).

A strikingly different behavior is observed when the tip is placed over a glass substrate coated with a 50 nm Au film (FIG. 3b). The smooth gold layer is characterized by height variations with a distribution centered at h₀=1.7 nm (standard deviation σ_{FWHM}=1.3 nm, FIGS. 4f and 4k). For illumination doses above 4 MW/cm², the spectrum splits into two fully resolved spectral lines, corresponding to the contributions from the hot (apex; line below 500 cm-1) and cold (shaft; line at 521 cm⁻¹) parts of the Si material that occupy the collection volume of the objective lens (inset FIG. 4d). At these higher laser intensities, we observe a large 30 cm⁻¹ shift in spectral line position, indicating a temperature change of the tip in excess of ΔT=1180 K (FIG. 4d). As revealed with Raman mapping, the “hot” material is found primarily within half a wavelength's distance from the apex (mapped at 480 cm⁻¹), whereas the colder part of the tip within the detection volume remains at ambient temperature (mapped at 521 cm⁻¹ The temperature near the apex exceeds the material melting point (1683 K), leading to the deformation and damage of the tip. FIGS. 4g and 4h show SEM post-experimental images of tip apexes, confirming melting of the material and apex detachment. Note that heat-induced pinching of the shaft occurs at a distance of 150-250 nm from the apex, which is consistent across all tip heating experiments. Raman thermometry thus indicates the presence of an efficient optical absorption mechanism when Si probe is in the proximity of a gold surface with fine nanoscale structure. Meanwhile, this mechanism is absent when the probe is place over a bare glass surface.

The power absorbed by the volume V, when irradiated with the flux I₀ can be written as P=αVI₀, where α is the absorption coefficient of the material. In the case of the Au surface, one may expect re-distribution and local enhancement of the optical field at protrusions^{45,46}. However, the Raman signal of Si remains constant over the entire surface of the smooth Au film, indicating the absence of highly localized hot spots beyond the lateral resolution of the experiment (~15 nm). This is consistent with the observed surface roughness (h₀=1.7 nm±0.65 (FIG. 4j), which is well below the spatial scale needed to support surface plasmon resonances⁴⁵.

The heat dynamics in solids at the nanoscale can be rather complex, as diverse mechanisms can play a role⁴⁷. In order to obtain reasonable estimates of the expected temperature of the silicon tip, we carry out FDTD/FEM simulations. From the simulations it is clear that, for a hemispherical Au protrusion of 2 nm, the penetration depth of the near-field into the Si tip apex is limited to 2-3 nm. The resulting field distribution gives rise to an estimated temperature increase of ΔT~25 K at the tip apex under the maximum illumination conditions. In comparison, the simulations show that the temperature change of the Au substrate is much smaller due to its high thermal conductivity. We also note that the simulated temperature distribution in the tip reveals a plateau beyond a depth of z=170 nm, which grows more evident as the laser intensity is increased. This geometry-dependent thermal bottle-neck is likely enhanced by the decrease of thermal conductivity with temperature⁴⁸, and the size-dependent effect ΔT(z)~zT/κ\hat{ }3 ∂κ/∂T 26. These simulated results are in excellent agreement with the experimental observations (FIGS. 4g and 4h), which reveal tip separation through melting at z~165 nm.

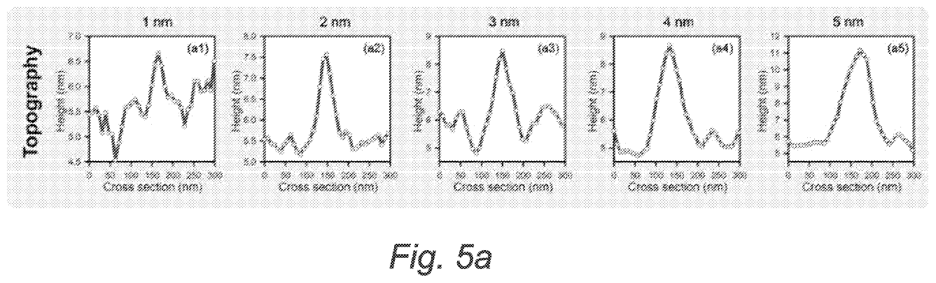

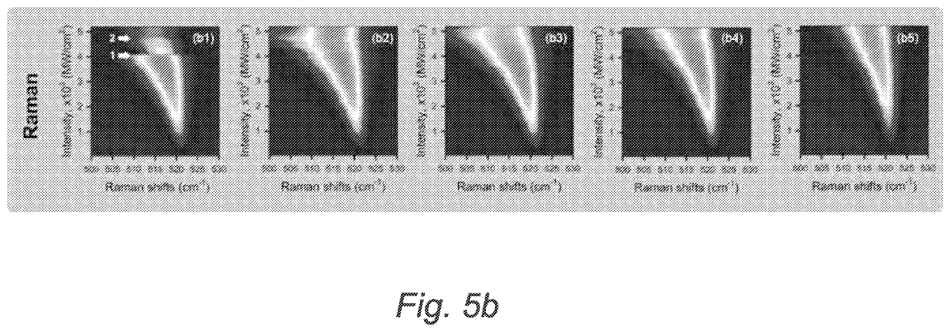

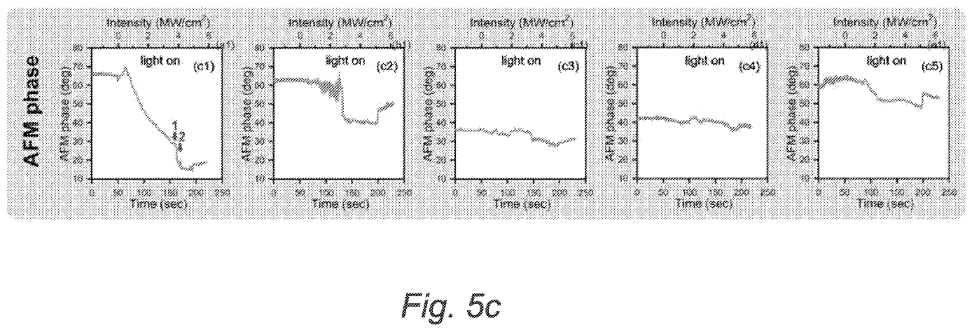

Both experiments and simulations point out that neither plasmonic nor geometry-dependent field enhancement alone can serve as the primary mechanism for the observed optical heating of the Si tip. To further confirm this notion, we perform measurements when the Si tip is placed over Au structures of a well-defined size. For this purpose, the film is analyzed by AFM imaging of multiple individual and isolated Au structures within the 1 to 5 nm range (FIG. 5a1-5e1). We record both the temperature dependence of the Raman spectrum as well as the cantilever phase φ, which serves as another probe that is sensitive to changes in the tip-sample interaction. The phase is especially sensitive to the thermal expansion/contraction of the tip apex or the sample, which is particularly extreme during melting and deformation.

We observe a clear inverse relationship between particle size and optical heating, as revealed by the intensity dependent Raman spectra (FIGS. 4b2-4e2) and phase measurements (FIGS. 5a3-5e3). For a ~1 nm Au structure, the Raman spectra indicate significant optical heating (ΔT>1500 K), corroborated by the dramatic changes in the cantilever phase, both pointing to melting of the tip. On the other hand, when the tip is brought into close proximity of structures larger than 3 nm, the temperature change is much smaller (ΔT<200 K for 5 nm) and the tip apex remains fully intact. Note that because of irreversible changes in tip morphology, we have used different AFM cantilevers for different experiments. The observed temperature trends are reproducible with every cantilever used and over each gold structure identified. For example, as seen from FIG. 5a2-5e2, below a laser intensity of 3 MW/cm² the temperature change is fully reversible and the tip apex remains intact. These experiments clearly show that the optical absorption in Si grows much stronger when the size of the light-confining nanostructures is decreased from 5 nm to 1 nm.

As a control experiment, we perform similar measurements with Si AFM cantilevers that are coated with a 30 nm Pt/Ir film. Using the cantilever phase as the readout, we observe limited variation upon increasing the laser intensity, indicating insufficient optical heating and no structural damage of the tip or the sample. This observation underlines that close proximity of bare Si to a nanometer size structure is required for the enhanced optical absorption in Si.

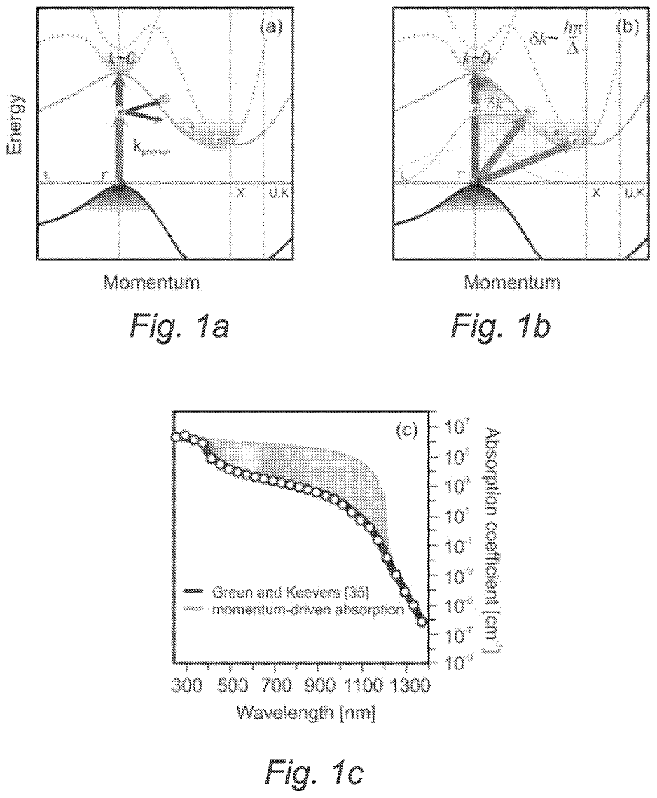

The anomalous heating of bare Si near the nm structure, the efficiency of which is inversely proportional to particle size, cannot be explained through field enhancement in the context of indirect optical transitions in Si. On the other hand, the highly localized optical fields at the nanostructures possess a momentum distribution that is inversely proportional to the spatial confinement, i.e. δk~2πℏ/Δr (FIG. 1). At Δr~1-5 nm this distribution becomes comparable to the change of momentum required for indirect electronic transitions in Si^{25,29}. This paves the way for an alternative mechanism, wherein the momentum is borrowed from the field, rather than from the lattice, to enable direct optical transitions (FIG. 1b).

It is reasonable to assume that the confined field distribution near a nanometer-sized object located at r can be modeled as E(r)=E₀e^{-r}^{²}^{/2σ}^{²}. Under these conditions, Equation 2 can be rewritten as:

$${W}_{{nn}^{′}} ( k , Δ k ) ≅ \frac{2 π}{h} {( \frac{e {E}_{0} ℏ}{ω m c} )}^{2} {\vert 〈 {n}^{′} ( k + Δ k ) \vert e ∇ \vert nk 〉 \vert}^{2} σ {e}^{- {σ}^{2} Δ {k}^{2}} δ ( ℏω - [ {E}_{{n}^{′}} ( k + Δ k ) - {E}_{n} ( k ) ] ) , \qquad ( 3 )$$

where e is the unit vector along the polarization direction of the incident light. Equation 3 indicates that indirect transitions of different Δk are weighted by a Gaussian function, as illustrated by the momentum distributions around the Γ point in FIG. 3b. For a given nanostructure, the transition rate is now given by the integration over all possible transitions within the momentum distribution Δk:

$${W}_{{nn}^{′}} = {\int }_{k - space} {W}_{{nn}^{′}} ( k , Δ k ) d Δ k . \qquad ( 4 )$$

After integration over k-space, the transition rate is drastically enhanced, transforming Si into a blackbody absorber for energies above the band edge,^{16,17} as hypothesized in FIG. 4c.

Given that the lattice constant of Si is a=0.54 nm, the first Brillouin zone spans π/a=5.79 nm⁻¹. To cover the T-X distance in reciprocal space²⁸ a confinement of Δr~0.7 nm is needed, which would permit direct momentum-enabled transitions at 1.1 eV (~1130 nm) in silicon (purple arrow and Gaussian momentum distribution in FIG. 3b). For higher photon energies (transitions closer to the direct bandgap of Si) the required amount of confinement is less so that larger Au structure can be used, for instance Δr~1.4 nm (633 nm, 1.96 eV) and Δr~2.8 nm (532 nm, 2.33 eV). This analysis highlights that the presence of structural confinement down to 0.7 nm (4.5 nm⁻¹) offers a mechanism for increasing the absorption coefficient of Si across the visible and near-infrared spectral range (FIG. 4c).

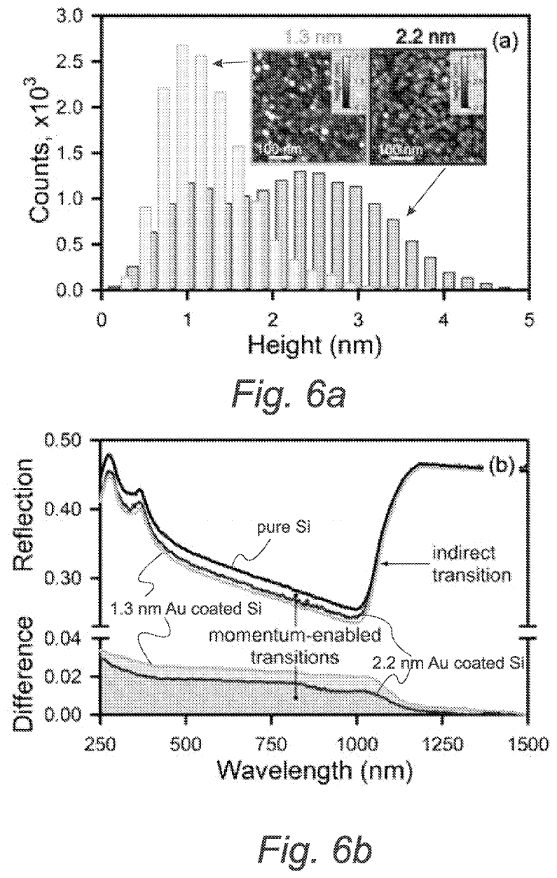

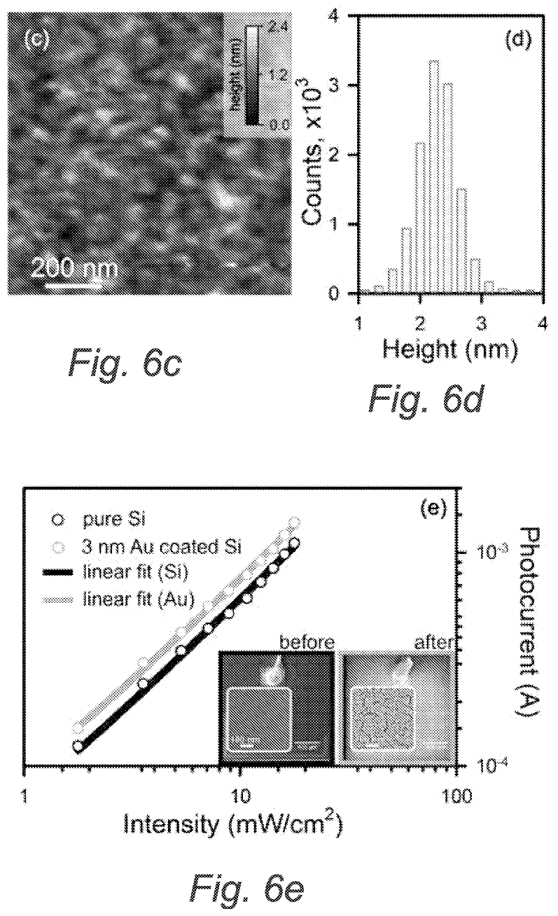

The proposed photon momentum expansion mechanism offers a consistent explanation for the enhanced optical absorption observed in the Si tip measurements. We seek to independently verify whether such effects can also be observed in different experimental geometries. For this purpose, we characterize the optical reflection off Si wafers that have been coated with Au structures of different sizes. Deposition of nanoscale structures on Si surface and within the crystal bulk have been the subject of active research in an effort to enhance the efficiencies of solar cells^{11, 49-51} and photodetectors52. Previous work has aimed to increase the DOS through local field enhancement via the plasmonic mechanism, using larger (>20 nm) particles and structures. In contrast, here we use non-plasmonic Au structures that are significantly smaller, namely in the 1-2 nm range. In these experiments, we deposit Au nanoparticles of a particular size distribution to form single layer films in direct contact with the Si surface. FIG. 6a shows AFM images and the height distribution for samples prepared with ~1.3 nm and ~2.2 nm particles. The reflection spectra are obtained with an integrating sphere in diffuse reflection mode (see Methods) and are shown in FIG. 5b. The spectral profiles are similar at low photon energies and show a characteristic change in reflection around 1100 nm, which is associated with the onset of indirect bandgap absorption. At energies above the indirect bandgap, the spectra are visibly different, revealing a reduced reflection, which grows more significant as the particle size decreases (FIG. 5b). These observations are in agreement with the momentum expansion approach, which is inversely proportional to particle size. Note that the reflection spectra are devoid of any signatures reminiscent of plasmonic resonances, as expected for Au structures that are smaller than 5 nm.

Second, using a different sputtering approach, we also deposit Au structures on the top surface of the photosensitive layer of a conventional Si photodiode. A representative AFM image of the deposited Au structures, along with their height distribution, is shown in FIGS. 6c and 6d. FIG. 6e shows the photocurrent detected from the clean (blue) and coated (orange) devices, measured as a function of the incident intensity of a 633 nm laser light source. The data clearly shows an increase of detector responsivity from R₀=0.33 A/W to R_{M}=0.42 A/W, or nearly 30% in the amount of detected photoconduction electrons, despite the presence of Rayleigh scattering at larger Au structures and islands.

### 1.2 Conclusions

Previous works, aimed at increasing the absorption of light in silicon, has focused primarily on field-enhancement mechanisms. Various effects have been leveraged to redistribute the far field intensity I₀ to locally confined intensity I=g²I₀, where g is the field enhancement factor, in an attempt to increase the absorbed power within a particular volume V to P=α_{indirect}VI=α_{indirect}V g²I₀⁴⁹⁻⁵¹. In the present work, we achieve absorption enhancement via a different route, namely by the anomalous optical properties of silicon that are manifest when the indirect semiconductor is put in close proximity to structures of <3 nm in size. First, our TERS experiments with Si tips reveal an unusual optical heating effect at the nanoscale. Second, we have observed a similar enhanced optical response in reflection measurements on Si wafers decorated with nm-sized gold structures and in photocurrent measurements with Au-coated Si photodiodes. These phenomena cannot be explained through surface plasmon or geometry-dependent mechanisms, as these are negligible for structures of this size. In addition, the absorption enhancement is inversely proportional to the size of the structures (FIG. 4 and FIG. 5), which is opposite to what would be expected for conventional field-enhancement effects.

The acquisition of momentum by highly confined photons allows an increase of the absorbed power P=α_{direct}VI₀ through the absorption coefficient of the medium α_{direct}. This enhancement is not limited to the momentum matching from Γ to X points as shown for simplicity in FIG. 4b. For a given photon energy, a broad momentum distribution enables other transitions from multiple points and in any direction across the Brillouin zone, as long as available energies and momenta are conserved. In contrast to relatively narrow spectral width of plasmonic or geometry-governed resonances, the photon momentum expansion provides enhancement of the optical absorption from the ultraviolet to the near-infrared, turning an indirect semiconductor into direct broadband absorber—a black body across 3 spectral octaves. The experimental results presented here provide an interesting opportunity to reconsider the role of photon momentum in light-matter interactions. With current advances in semiconductor fabrication technologies approaching a resolution of sub-1.5 nm, expanded photon momentum has the potential to strongly impact optical spectroscopies, light sensing, emission and light-energy conversion.

### 1.3 Methods

### 1.3.1 Atomic Force Microscopy

The multimode scanning probe microscope Prima (NT-MDT) was utilized for visualizing a topography of intrinsic Si wafer with sputtered Au nanoparticles. AFM cantilever (VIT_P) was made of antimony-doped single crystal silicon (n-type, 0.01-0.025 Ohm-cm). The tip height is 14-16 μm, the tip curvature radius is 30 nm, the resonant frequency was 300 kHz.

### 1.3.2 Light Reflection Measurement

The Au film coated Si wafers were measured with a spectroscopic ellipsometer (VASE, J. A. Woollam) within the spectral range of 250-2500 nm. The incident angle was 70°.

### 1.3.3 Far- and Near-Field Raman Spectroscopy and Microscopy

Raman spectra and maps were captured with a multi-purpose analytical instrument NTEGRA SPECTRA™ (NT-MDT) in both upright and inverted configuration. The confocal spectrometer was wavelength calibrated with a crystalline silicon (100) wafer by registering the first-order Raman band at 521 cm⁻¹. A sensitivity of the spectrometer was as high as ca. 2500 photon counts per 0.1 s provided that a 100× objective (N.A.=0.7), an exit slit (pinhole) of 100 μm and a linearly polarized light with the wavelength of 632.8 nm and the power at the sample of 10 mW were used. No signal amplification regimes of a Newton EMCCD camera (ANDOR) was used.

128×128 pixel Raman maps were raster scanned with an exposure time per pixel of 0.1 s and were finally collected with the EMCCD camera cooled down to −90° C. Raman spectra within the range of from −2000 to 2000 cm⁻¹ were registered with a spectral resolution of 0.1 cm⁻¹ and using the Echelle grating.

### 1.3.4 FDTD/FEM Calculation

3D simulation of optical absorption of a cone-shaped Si tip under cw focused illumination was performed by using an Ansys/Lumerical FDTD solver. A mesh overlayer of 0.1 nm was utilized around the Au bump and the Si tip apex and a rougher 1 nm mesh for the rest of the structure. Perfectly matching layers were used as boundary conditions for three directions. The optical and thermal properties of Si and Au were imported from the Ansys/Lumerical material database. The Si tip apex was exposed to a 632.8 nm focused laser light (NA=0.7) with the intensity of 5 MW/cm². The temperature profile was calculated through an Ansys/Lumerical FEM solver in the steady state regime. The thermal conductivity of all constituents is assumed to be temperature-independent. The boundary condition of T=300 K was set at the zₘᵢₙ=−3500 nm of the 20×20×5 μm³ simulation region.

### 2. Electronic Raman Scattering in Semiconductor Glass

This study delves into the role of expanded photon momentum in emission from semiconducting systems. Our experimental results shows direct connection between the emission from disordered or structured semiconducting systems and electronic Raman scattering (ERS), a phenomenon exclusively considered in metallic systems thus far. Here, we demonstrate that ERS is also evident in disordered semiconductors, driven by the expansion of photon momentum when light is confined at nanoscale inclusions. Essentially, the observed ERS resembles Compton scattering, but now with visible photons.

One of the first observations of ERS in semiconductors has been linked to direct optical transitions between a light-hole band and a heavy-hole band,⁵⁵ an effect distinct from vibrational Raman scattering (VRS) where the initial and final electronic states remain identical. We attribute the observed emission to ERS transitions from states within the bandgap, which, in the context of the Mott-Davis model for disordered semiconductors,^{56,57} are expected to be present in the cross-linked silicon glass studied here. Because such Urbach states constitute trapped states for the electron, transitions in close proximity to the conduction band require a source of momentum. Although lattice phonons have been proposed to supply the necessary momentum, higher-energy transitions from deep trapped states would require the involvement of multiple phonons,⁵⁸ thus severely limiting the probability of such transitions. We propose that transitions from these states are enabled instead by electron-photon momentum matching, a result of quantum confinement,⁵⁹, particularly in a disordered medium. The concept of expanded near-field photon momentum has previously been proposed as a plausible explanation for enhanced interband two-photon excitation⁶⁰ as well as intra-band transitions in gold nanostructures.⁶¹ More recently, momentum expansion in plasmonic two-dimensional systems has been discussed, focusing on multipolar, spin-flip, and multi-quanta emission processes.⁶² Here we suggest that the existence of near-field photon modes with expanded momenta in a Si glass provides the necessary momentum to facilitate ERS transitions from trapped states in the bandgap. This effect is similar to Compton scattering, though with visible light photons.

In the context of disordered semiconductors, we revisit an idea proposed and developed by Mott and Davis^{57,63} and use it to explain the PL phenomenon. The model is based on the concept of dangling bonds at vacancies, divacancies or nano-voids. It introduces an excess electronic density of states within the forbidden gap,⁶⁴ forming an Urbach bridge of electronic states across the semiconductor bandgap. This bridge enables new electronic Raman transitions, including low-energy intra-band transitions near the Fermi level (1-ERS), higher energy band from inter-band transitions in the extended tail near the conduction band (h-ERS) and its heavy tail indicating optical transitions from deep states in the Urbach bridge.

These emissions exhibit a strong correlation with structural size, a relationship that can be explained through the concept of electron-photon momentum matching. Given the direct link between optical signals and the formation of cross-linked semiconductor glasses, the findings presented here pave the way for expanding conventional optical spectroscopy for both chemical (energy) and structural (momentum) studies of disordered solids.

### 2.1 Results and Discussion

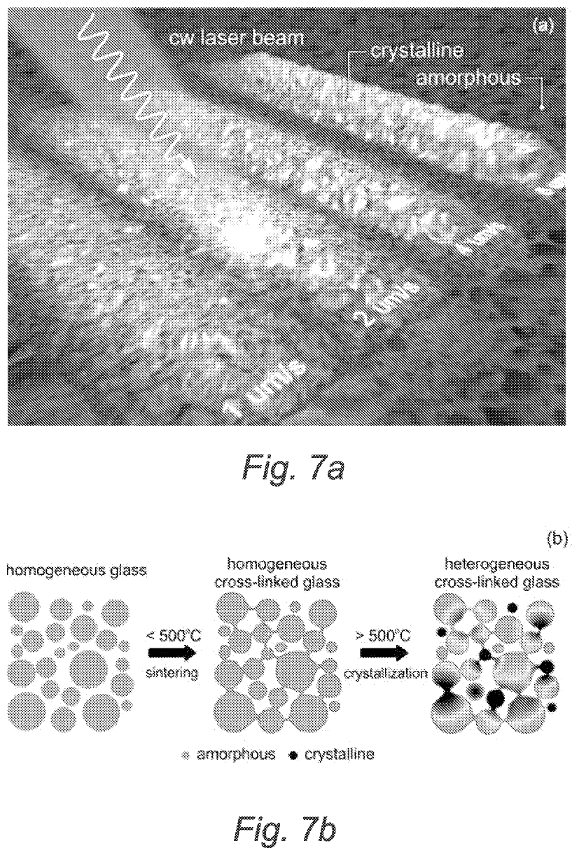

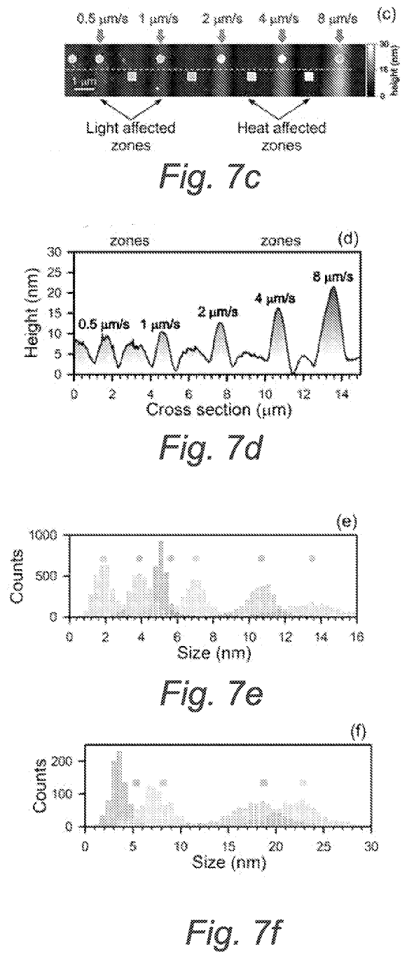

First, we offer a strategy to produce samples where both crystallinity and structure size are known and formed in a controlled fashion. We consider a bottom-to-top approach, i.e. from a disordered state to a more ordered material state, by which amorphous silicon (a-Si) transforms in part into crystalline silicon (c-Si) through light-assisted thermal impact. This approach allows efficient photon absorption in an amorphous matrix, followed by light emission at c-Si nanocrystal inclusions. To accomplish this, we deposit a 300 nm thick a-Si film on glass using chemical vapor deposition (see Methods). The film is then subjected to a tightly focused cw laser beam, which is scanned to write an array of straight lines at different scanning speeds (FIG. 7a). The high light absorption (α=83 870 cm-1 at 633 nm35) and low thermal conductivity (36) of a-Si give rise to local heating. In areas where light-induced temperature changes do not exceed 500° C., this procedure results in the sintering of amorphous structures forming a homogeneous cross-linked glass (FIG. 7b).^{67,68} In areas where temperature exceeds 500° C., an amorphous-to-crystalline phase transition occurs, and a heterogenous cross-linked semiconductor glass is formed. The resulting film, ‘foamed’ by light, represents a heterogeneous disordered matrix in which electronic, optical and thermal properties vary on the nanometer scale.

In our experiment, the local degree of crystallinity is determined by the speed of the scanning laser beam with an intensity of 2.5 MW/cm², which was set to 0.5, 1, 2, 4 or 8 μm/s.

An AFM topography map in FIG. 7c shows that an array of stripes can be easily formed, where their height increases proportionally with the scanning rate, reaching a few tens of nanometers. For intensities above 3 MW/cm², we observe the formation of bubbles on the surface of the film. These bubbles are prone to bursting, leading to the formation of significant protrusion areas that were used to assess the thickness of the initial a-Si film. Within the formed glass surface, we identify two distinct areas. The first is the light-affected zone (LAZ), which represents the area directly exposed to the laser radiation. The second is the heat-only affected zone (HAZ), which encompasses the portion that remained unexposed to the laser and was solely influenced by diffusion of heat.

FIG. 7d shows structural growth within the LAZ. Changes in the film topology are caused by more a compact arrangement of atomic Si upon crystallization, leading to relaxation of intrinsic local stress to minimize the Gibbs energy. Here, we come across a counterintuitive observation: extended exposure times result in inferior crystallization and smaller structural formation. These can be explained by the larger thermal conductivity of c-Si (κ_{c-Si}=147 W/mK)) compared to that of a-Si (κ_{a-Si}=1.7-2.2 W/mK). For this process, a negative feedback loop is initiated, causing crystallization to cease as a result of efficient heat transfer. The local temperature may drop below the threshold of 500° C., while the film morphology continues to change due to sintering (FIG. 7e).

The dissipation of heat beyond the LAZ induces changes in morphology and structure formation in the HAZ. FIG. 7f illustrates a broader distribution of surface roughness in HAZ compared to LAZ. It can be seen that HAZ differs from LAZ by the lack of a crystalline (c-Si) phase. The degree of crystallinity in each zone is monitored using vibrational Raman scattering (VRS).⁵⁴ While LAZ is clearly rich of c-Si, the temperature in HAZ does not exceed the required threshold. Meanwhile, crystallization in HAZ can be triggered by pressure and local stress⁶⁹ at amorphous/crystalline interfaces, an effect that is observed in our experiments near the zone boundaries (FIG. 7f). In summary, laser writing yields a narrow distribution of nanostructures sizes within both LAZ and HAZ, as estimated from the surface roughness. This model system proves invaluable for exploring structure- and phase-dependent photoemission.

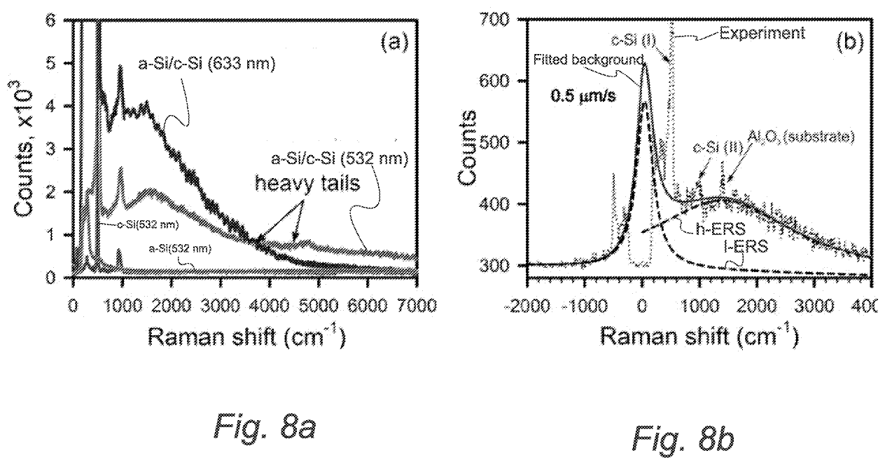

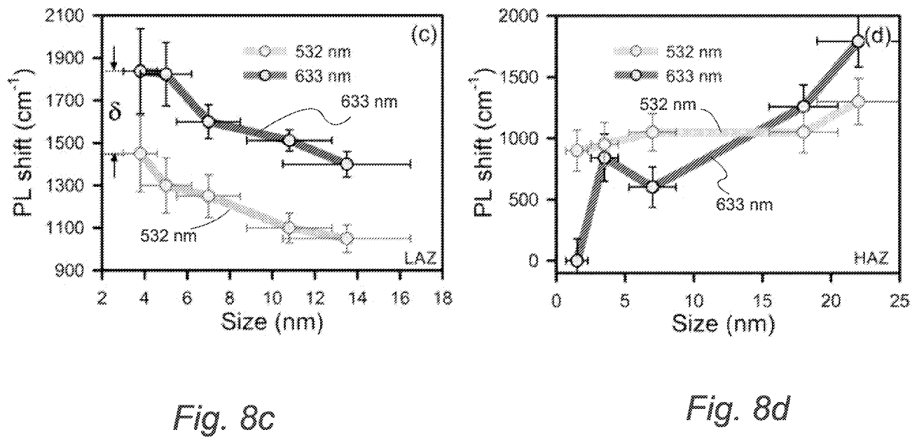

The Raman spectrum of LAZ, obtained at a position where a writing speed of 0.5 μm/s was applied, is shown in FIG. 8a. A rich emission spectrum covering a broad energy range is observed, where the presence of a crystalline phase can be inferred from the lines at 521 cm⁻¹ and 960 cm⁻¹, attributed to the first- and second-order (optical) phonon modes of c-Si. The broad emission band, extending well beyond 5000 cm⁻¹, peaks near 1700 cm⁻¹ for either the 532 nm or 633 nm excitation wavelength. The overall invariance of the emission maximum with excitation color rules out a dominant role for radiative recombination originating from thermalized electron populations in the conduction band and holes in the valence band. In addition, the observation of the emission at large Stokes shifts (>3000 cm⁻¹), which we refer to as the heavy tail, cannot be accounted for in the context of thermalization of electrons and holes. Phonons are required for the thermalization process, yet the vibrational density of states (v-DOS) of the phonon bath is expected to be reduced for nanoscale structures, which can prolong the duration of thermalization by an order of magnitude.^{52,70} A lower v-DOS becomes negligible for structures smaller than a few nm, so that the probability of emitting or absorbing phonons, needed for electron thermalization and indirect phonon-assisted transitions, is significantly reduced. Moreover, quantum confinement should raise the bottom edge of the conduction band at the T-X point of the Brillouin zone by 1 eV. This means that the 633 nm photon carries insufficient energy to induce indirect inter-band transitions in such sub-nanometer structures. These considerations are at odds with a model that relies on emission from radiative electron-hole recombination, but comply with the ERS model for emission.

FIG. 8b displays the full LAZ emission spectrum, showing spectral features on both the Stokes and the anti-Stokes sides. In the following, we ignore the optical phonon signatures and focus solely on the broader spectral features. Using a regularized least squares method, we decompose the spectral response into two distinct bands denoted as l-ERS (low-energy ERS near Fermi level, red dotted line, FIG. 8b) and h-ERS (high energy shifted ERS band, green dotted line, FIG. 8b). We note that both l-ERS and h-ERS are absent in bulk c-Si—they only appear after the light-induced structuring in the a-Si material.

FIG. 8c presents the central energy shift of h-ERS as a function of structural size using an excitation wavelength of either 633 nm or 532 nm (depicted by the blue solid curves). These plots reveal a clear trend: a pronounced redshift of h-ERS as the structure size is decreased. Below, we argue that this observation provides evidence for ERS from trapped states in nanocrystalline inclusions in the a-Si matrix. We observe an opposite trend for the size-dependence of the h-ERS energy shift in HAZ. FIG. 8d shows a growth of the energy shift as the structure size is increased, which is observed for both excitation wavelengths. This latter phenomenon can be explained in the context of an amorphous semiconductor, which constitutes the only component in HAZ. In amorphous Si the energy band structure is smeared compared to the crystalline phase, associated with a decreasing bandgap when the structure size increases.^{71,72} In the case of unperturbed a-Si with a ~2 nm surface roughness, the h-ERS fully overlaps with l-ERS. As the a-Si film is subjected to heat, its roughness increases due to the sintering process, leading to a redshift in the h-ERS, a result of size-dependent band smearing.

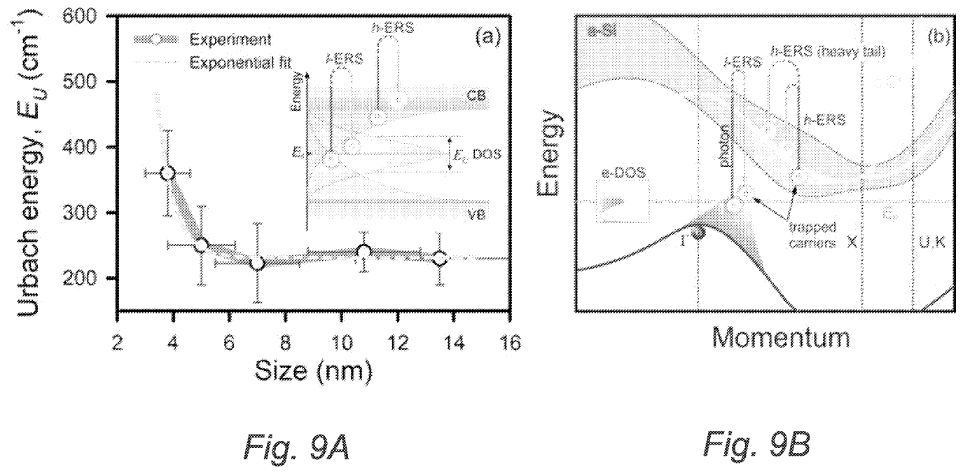

To explain the size dependent emission energy shift in LAZ, we propose an alternative explanation for the emission origin in cross-linked semiconductor Si glasses that is based on electronic Raman scattering enabled by electron-photon momentum matching, as depicted in FIG. 9a.^{53,54} This model considers that, in disordered semiconductors, localized electron states form an excess electronic density of states (e-DOS) across the forbidden gap, extending from the band edges down to Fermi level (FIG. 9b and inset FIG. 9a), as was predicted by Mott et al.^{57,63} Molecular dynamic simulations reveal that defect-induced Hellman-Feynman forces govern the forbidden gap,⁴³ linking the upper valence edge band and the bottom conductance edge band. We term this electronic continuum “the Urbach bridge,” that is conceptually illustrated in FIG. 9b and the inset of FIG. 9a. The size-dependent closing of the bandgap transforms an amorphous semiconductor into a quasi-metal and enable the observation of indirect and direct optical transitions.

Within this model, the observed l-ERS emission can now be attributed to optical transitions in the vicinity of the Fermi level. Here, we establish a connection between the observed l-ERS and emission effects that are associated with photon momentum, phenomena previously reported in rough metals,^{60,61} disordered semiconductors,⁷⁴ and high entropy oxides.⁷⁵ Similar to metals, the l-ERS peak remains centered at the Rayleigh line for varying sizes of the crystallites, yet a clear correlation exists between its linewidth (Γ) and structure size (FIG. 9a). An empirical connection between the disorder-driven Raman linewidth (Γ) and Urbach energy (E_{U}), i.e. Γ~E_{U} has been previously established.^{76,77} Our data demonstrates that the l-ERS linewidth (Urbach energy) exhibits an exponential growth that is inversely proportional to the structure size (FIG. 9a). At 4 nm, the l-ERS linewidth reaches the value of 43 meV (350 cm⁻¹), while for larger structures, it asymptotically approaches the thermal energy kT≈23meV (200 cm⁻¹). It is crucial to note that the l-ERS peak diminishes as the cross-linked glass undergoes excessive or full crystallization.

Applying a similar rationale, the h-ERS and its energy redshift is explained as an electronic Raman process linked to optical transition from the Urbach bridge to the conduction band (FIG. 9b). To extract an electron from the trapped state within the bridge in the mobility gap, a change in electron momentum is necessary.⁷⁸ While previous studies by Zhang and Drabold⁷⁹ have explored the use of phonons to assist in this transition, the authors acknowledge that the energy of a single phonon would not suffice for enabling the transition deep from the mobility gap as observed by the emission's heavy tail (>4000 cm⁻¹). Alternatively, both energy and momentum required for such transitions can be supplied by the photon confined within the nanostructure. The photon's large energy and expanded momentum enable indirect optical transitions from deeper states within the Urbach bridge to the conduction band. This notion is further supported by the observed difference in the heavy tail intensity when using excitation wavelengths of 532 nm or 633 nm (FIG. 8a). While the center of mass of the h-ERS spectrum remains similar for both cases, the heavy tail appears slightly more intense with the use of 532 nm excitation. While the width of the phonon's k-spectrum in both cases is fully defined by spatial nanostructure size,⁷⁹ confinement of a 532 nm photon should yield a higher optical density of states compared to a confined 633 nm at the same structure. Hence, for a higher amplitude k-spectrum at 532 nm, the wings of the spectral distribution contribute more significantly to the transitions where larger momenta are required.

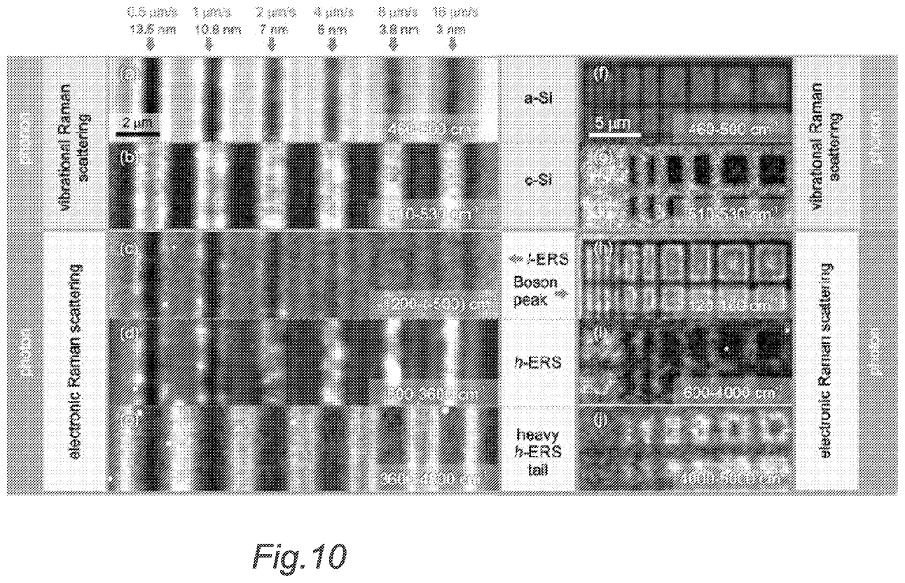

To facilitate a careful examination of the data within the context of the proposed Urbach bridge concept, FIG. 10 shows Raman spectral maps summarizing the overall trends and correlations observed for two distinct types of structures. The first type, extensively discussed earlier, consists of 1D arrays (FIG. 7, FIG. 10a-e). The second one comprises a 2D network of cross-linked semiconductor glass (FIG. 10f-j). It has been fabricated on a similar a-Si film by scanning the laser beam and forming a network of crossed protrusions with a gradually adjusted pitch, as imaged in AFM topography. The spectral maps acquired from these structures not only establish clear correlations but affirm a direct connection between structure size, degree of crystallinity, and their corresponding spectral responses.

FIGS. 10a-b and 10f-g show spectral maps of vibrational (VRS) Raman scattering originating from a-Si and c-Si. An inversion of the VRS maps for a-Si and c-Si is evident. Following the discussion above, the degree of crystallinity is intricately tied to the writing speed, driven by a substantial difference in thermal conductivity between a-Si and c-Si. Hence, in the case of 1D array, the crystallization in the LAZ and, consequently, the c-Si VRS are depressed when a slower writing speed (0.5 μm/s) is used. At the same time, the boundaries between LAZ and HAZ contain substantial c-Si nanostructures, as confirmed by AFM (FIG. 7b), causing these regions to light up in this spectral range. With an increase in writing speed, crystallization proceeds more uniformly, leading to a decrease in the VRS intensity at HAZ boundaries.

ERS maps (l-ERS and h-ERS) for both types of samples follow the spatial distribution of structural sizes and degree of crystallinity across their surfaces (FIGS. 10c-e and 10i-j). To visualize l-ERS for the 1D array, we plot the integrated signal at the anti-Stokes wing in the −1200-(−500) cm⁻¹ spectral range (FIG. 10c), avoiding contributions from other spectral features, particularly the Boson peak. In line with the discussion on data in FIG. 9a, the trend shows an increase in the integrated signal (l-ERS width, FIG. 10c) with a decrease in structure size. Furthermore, a Boson peak map at 140 cm⁻¹ for the 2D network is plotted in FIG. 10h. The Boson peak emerges in disordered systems due to the hybridization of plane-wave bulk and confined phonons.^{80,81} As can be seen on the spectral map, this peak intensifies with crystallization near the LAZ/HAZ interface due to an increase in v-DOS of bulk phonons—an observation consistent with the VRS maps (FIGS. 10a-b and 10f-g) discussed earlier. The Boson peak, however, proves insensitive to thermal impact, as observed in HAZs, although it shows a slight degradation compared to that of a-Si. This phenomenon may be attributed to thermal-induced amorphization, resulting in increased roughness and stress relaxation.

The h-ERS maps, generated by integrating the signals above 600 cm⁻¹, are shown in FIGS. 10d-e (1D array) and 4I-J (2D network). In the case of the 1D array, the h-ERS intensity in LAZ increases with writing speed. These results corroborate earlier observations detailed in FIGS. 8c and 8d—the h-ERS energy shift is inversely proportional to the structure size. Following surface topography and the spatial distribution of c-Si nanocrystals, the h-ERS extends further away from LAZ and towards HAZ. The h-ERS maps of 2D network exhibit a similar trend (FIG. 10i-j). Here, an interesting observation is noted: multiple passes of the laser beam through closely packed spatial locations seem to influence morphology (or size range), but not the level of crystallinity. This conclusion naturally follows from the direct comparison between the c-Si VRS map (FIG. 10g) and the Si glass ERS map (FIG. 10i). In areas where multiple laser passes create a smaller pitch (left side of the map, FIG. 10i), the ERS signal intensifies. The closely packed pitch ‘foams’ the film, causing it to become more heterogeneous by blending amorphous and crystalline phases.

The spectral maps of the ERS heavy tail are presented in FIGS. 10e and 10j. Clearly, the h-ERS extends beyond the LAZ and the highest energy-shifted ERS signals are observed well into the HAZ. We note that the HAZ is not expected to contain large, fully developed c-Si structures, as preliminary confirmed by c-Si VRS (FIG. 10b). However, these areas may host crystal embryo's-sub-to-near nm Si crystallization nuclei-which can be present near the LAZ/HAZ interface and extend into the HAZ due to the pressure gradient between the zones.⁶⁹ These intriguing sub-areas can be referred to as pressure-affected zones (PAZ). A photon confined at such crystalline embryos carries both energy and a significantly large momentum, which can be transferred to an electron, facilitating the transition from deep trapped states within the forbidden gap to the conduction band (FIG. 9b). This process gives rise to a substantial energy-shifted ERS heavy tail, extending it spectrally well above 4000 cm⁻¹ and observable up to 7000 cm⁻¹. Such energy shifts cannot be explained using conventional electron-phonon interactions.^{59,73,82} To demonstrate the effect of pressure driven Si-formations, we conducted a series of experiments using an AFM cantilever. In these experiments, the tip was used in contact tapping mode to create pressure points on an a-Si film. The regions subjected to such pressure exhibit a significant increase in the heavy tail of h-ERS, while spectra show no presence of c-Si. Furthermore, a correlation between Boson peak and heavy tail ERS is clearly observed, specifically the dark inner frames in FIGS. 10h and the bright frames in FIG. 10j. Remarkably, these regions were not directly impacted by laser illumination. Nonetheless, the observed correlation suggests the presence of crystalline embryos formed by local internal stress when the film topology undergoes changes due to laser writing.

### 2.3 Conclusion

This work presents a detailed study of light emission in a heterogeneous cross-linked glass composed of c-Si nanocrystals embedded in an amorphous silicon matrix. With such a model sample at hand, we attempt to address a few outstanding questions regarding the origin of PL and discuss the emission spectrum in relation to crystal phase, size and photon excitation energy. Our findings challenge the conventional notions of phonon-assisted fluorescence in quantum confined systems. To interpret our observations, we revisit the concept proposed in 1967 by Mott and Davis.⁵⁶ They suggested that a continuum of energy states forms in the forbidden gap once disorder and crystallinity are presented at the nanoscale. This extended e-DOS establishes a quasi-continuous connection between the conduction and valence bands, referred to here as an Urbach bridge. We propose that intra- and inter-band optical transitions within Urbach bridge underlie the observed emission effect.

The observation and spectral analysis of the l-ERS leads us to suggest electronic Raman scattering as the dominant mechanism of emission, a phenomenon previously observed and explained in the context of extended photon momentum on nanoscale asperities of metal surfaces⁶⁰ and even individual gold particles.⁶¹ The electronic Raman nature of the emission is further supported by a substantial h-ERS redshift, its correlation with size, and lack of dependence on excitation photon energy.

In our proposed model, both emission features originate from the Urbach bridge, a conclusion supported by the synchronous appearance and evolution of the signals upon mixing amorphous and crystalline phases. Both features disappear when the system fully transforms to bulk c-Si. The l-ERS on the Urbach bridge is associated with ERS transitions near the Fermi level. We argue that confined photons with expanded momentum likely exist in a nanostructured a-Si/c-Si matrix. Inter-band optical transitions from the Urbach bridge to the conduction band are responsible for h-ERS. This insight helps explain its heavy tail (>4000 cm⁻¹ energy shift) originating from deep states in the forbidden gap and to the conduction band. These transitions require the smallest structural confinement and large photon momentum available at embryonic c-Si sites. The size dependence of the l-ERS and h-ERS underscores their potential utility as spectroscopic probes for quantifying the structural disorder in vitreous semiconductors and empower optical spectroscopy to enable structural analysis of disordered solids.

Lastly, we would like to highlight an apparent similarity between the ERS and Compton scattering processes. The Compton effect occurs when a propagating photon with a relatively large momentum, i.e. X-ray, scatters upon an electron.⁸³ Similarly, the ERS phenomenon discussed here is driven by a confined visible photon with enhanced momentum, scattering on an electron in a trapped state within the forbidden energy gap. The matching of electron and photon momenta enables these light-matter interactions that are otherwise forbidden. While one of the conventional and efficient methods to confine light involves utilizing plasmon resonance, its efficacy diminishes when the structure size is less than 5 nm. Meanwhile, structural singularities, including but not limited to vacancies, dangling bonds, crystalline embryo's, induce an electrostatic lightning rod effect,⁸⁴ significantly expanding photon momentum and surpassing the plasmonic effect.^{85,86}

### 2.4 Methods

### 2.4.1 Sample Preparation

For the a-Si thin film deposition, the modified Gatan Precision Ion Polishing System (PIPS, Gatan Inc.) was used as a sputter coater. Similar to Ref.55, our modification of the PIPS enables coating of bulk sample surfaces and the deposition of thin films of a variety of materials. An advantage of using the PIPS for the latter purpose is the oil-free vacuum system, which allows films to be deposited with minimal carbon contamination. The sputter source was a piece of monocrystal wafer about 5 mm in diameter mounted on the standard specimen holder post. This milling system consists of two rare-earth Penning-type ion guns (PIGs), which were used together to speed up the sputtering process. The angle between guns and rotating target source material was +150 and did not change during the process. The system operated at the maximum acceleration voltage of 8 kV. The wafer source was sputter-cleaned for 2 minutes (pneumatic shutter in closed position) before the deposition process started. The vacuum level prior to deposition was typically 10-3 Pa or better. Typical sputtering times for producing amorphous thin films were in the range of 30 to 90 minutes, depending on the sputter source and thickness required.

### 2.4.2 Atomic Force Microscopy

The multimode scanning probe microscope Prima (NT-MDT) was utilized for visualizing a topography of light-structured silicon glasses. AFM cantilever (VIT_P) was made of antimony-doped single crystal silicon (n-type, 0.01-0.025 Ohm-cm). The tip height is 14-16 □m, the tip curvature radius is 30 nm, the resonant frequency was 300 KHz.

### 2.4.3 Scanning Electron Microscopy

The elemental composition, and morphology of the samples were studied by the Auriga Crossbeam Workstation (Carl Zeiss AG, Oberkochen, Germany), equipped with an INCA X-Max silicon drift detector (Oxford Instruments, Abingdon, UK) for energy dispersive X-ray microanalysis. For elemental analysis of Si diodes and wafers, an acceleration voltage of 5 keV, an analytical working distance of 4 mm, and an electron probe current of 75 pA were used.

### 2.4.4 Far- and Near-Field Raman Spectroscopy and Microscopy

Raman spectra and maps were captured with a multi-purpose analytical instrument NTEGRA SPECTRA™ (NT-MDT) in upright configuration. The confocal spectrometer was wavelength calibrated with a crystalline silicon (100) wafer by registering the first-order Raman band at 521 cm⁻¹. A sensitivity of the spectrometer was as high as ca. 1700 photon counts per 0.1 s provided that we used a 100× objective (N.A.=0.7), an exit slit (pinhole) of 100 □m and a linearly polarized light with the wavelength of 632.8 nm and the power at the sample of 10 mW. No signal amplification regimes of a Newton EMCCD camera (ANDOR) was used. Low-frequency Raman measurements were performed using a 633 nm Bragg notch filter (OptiGrate) with a spectral blocking window of 10 cm⁻¹.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### REFERENCES

[1] L. Pavesi, Front. Phys. 2021, 9, 786028.
[2] D. Liang, J. E. Bowers, Nat. Photonics 2010, 4, 511.
[3] W. Cao, H. Bu, M. Vinet, M. Cao, S. Takagi, S. Hwang, T. Ghani, K. Banerjee, Nature 2023, 620, 501.
[4] L. Canham, Handbook of Porous Silicon, Springer, 2014.
[5] B. Gelloz, in Handbook of Porous Silicon (Ed: L. Canham), Springer, 2014, Ch. 2.
[6] L. Pavesi, M. Ceschini, F. Rossi, J. Lumin. 1993, 57, 131.
[7] G. G. Qin, Y. Q. Jia, Solid State Commun. 1993, 86, 559.
[8] O. K. Andersen, E. Veje, Phys. Rev. B 1996, 53, 15643.
[9] S. Bayliss, Q. Zhang, P. Harris, Appl. Surf Sci. 1996, 102, 390.
[10] M. V. Wolkin, J. Jorne, P. M. Fauchet, G. Allan, C. Delerue, Phys. Rev. Lett. 1999, 82, 197.
[11] Pillai, S., Catchpole, K. R., Trupke, T. & Green, M. A. Surface plasmon enhanced silicon solar cells. 101, 093105, doi:10.1063/1.2734885 (2007).
[12] Bandiera, S. et al. Enhanced absorption by nanostructured silicon. 93, 193103, doi:10.1063/1.3021480 (2008).
[13] Yuan, H.-C. et al. Efficient black silicon solar cell with a density-graded nanoporous surface: Optical properties, performance limitations, and design rules. 95, 123501, doi:10.1063/1.3231438 (2009).
[14] Zhu, J., Yu, Z., Fan, S. & Cui, Y. Nanostructured photon management for high performance solar cells. Materials Science and Engineering: R: Reports 70, 330-340, doi:https://doi.org/10.1016/j.mser.2010.06.018 (2010).
[15] Wang, K. X., Yu, Z., Liu, V., Cui, Y. & Fan, S. Absorption Enhancement in Ultrathin Crystalline Silicon Solar Cells with Antireflection and Light-Trapping Nanocone Gratings. Nano Letters 12, 1616-1619, doi:10.1021/n1204550q (2012).
[16] Liu, X. et al. Black silicon: fabrication methods, properties and solar energy applications. Energy & Environmental Science 7, 3223-3263, doi:10.1039/C4EE01152J (2014).
[17 Otto, M. et al. Black Silicon Photovoltaics. 3, 147-164, doi:https://doi.org/10.1002/adom.201400395 (2015).
[18] Konedana, S. S. P., Vaida, E., Viller, V. & Shalev, G. Optical absorption beyond the Yablonovitch limit with light funnel arrays. Nano Energy 59, 321-326, doi:https://doi.org/10.1016/j.nanoen.2019.02.039 (2019).
[19] Nirmal, M. & Brus, L. Luminescence Photophysics in Semiconductor Nanocrystals. Accounts of Chemical Research 32, 407-414, doi:10.1021/ar9700320 (1999).
[20] Lv, J., Zhang, T., Zhang, P., Zhao, Y. & Li, S. Review Application of Nanostructured Black Silicon. Nanoscale Research Letters 13, 110, doi:10.1186/s11671-018-2523-4 (2018).
[21] Brus, L. E. et al. Electronic Spectroscopy and Photophysics of Si Nanocrystals: Relationship to Bulk c-Si and Porous Si. Journal of the American Chemical Society 117, 2915-2922, doi:10.1021/ja00115a025 (1995).
[22] Shalaev, V. M. Electromagnetic properties of small-particle composites. Physics Reports 272, 61-137, doi:https://doi.org/10.1016/0370-1573(95)00076-3 (1996).
[23] L. Canham, Faraday Discuss. 2020, 222, 10.
[24] S. Guha, P. Steiner, F. Kozlowski, W. Lang, Thin Solid Films 1995, 255, 119.
[25] C. Delerue, G. Allan, M. Lannoo, Phys. Rev. B 1993, 48, 11024.
[26] B. Delley, E. F. Steigmeier, Phys. Rev. B 1993, 47, 1397.
[27] F. Koch, V. Petrova-Koch, T. Muschik, A. Nikolov, V. Gavrilenko, Mat. Res. Soc. Symp. Proc. 1993, 283, 197.
[28] S. M. Prokes, O. J. Glembocki, V. M. Bermudez, R. Kaplan, L. E. Friedersdorf, P. C. Searson, Phys. Rev. B 1992, 45, 13788.
[29] M. S. Brandt, H. D. Fuehs, M. Stutzmann, J. Weber, M. Cardona, Solid State Commun. 1992, 81, 307.
[30] J. C. Vial, A. Bsiesy, F. Gaspard, R. Hérino, M. Ligeon, F. Muller, R. Romestain, R. M. Macfarlane, Phys. Rev. B 1992, 45, 14171.
[31] P. Bharadwaj, B. Deutsch, L. Novotny, Adv. Opt. Photonics 2009, 1, 438.
[32] M. Agio, A. Alu, Optical Antennas, Cambridge University Press, New York 2013.
[33] M. V. Rama Krishna, R. A. Friesner, J. Chem. Phys. 1992, 96, 873.
[34] W. D. A. M. de Boer, D. Timmerman, K. Dohnalova, I. N. Yassievich, H. Zhang, W. J. Buma, T. Gregorkiewicz, Nat. Nanotechnol. 2010, 5, 878.
[35] Bharadwaj, P., Deutsch, B. & Novotny, L. Optical Antennas. Adv. Opt. Photon. 1, 438-483, doi:10.1364/AOP.1.000438 (2009).
[36] Novotny, L. & Hecht, B. Principles of Nano-Optics. 2 edn, (Cambridge University Press, 2012).
[37] Lee, J., Crampton, K. T., Tallarida, N. & Apkarian, V. A. Visualizing vibrational normal modes of a single molecule with atomically confined light. Nature 568, 78-82, doi:10.1038/s41586-019-1059-9 (2019).
[3]8 Macfarlane, G. G. & Roberts, V. Infrared Absorption of Silicon Near the Lattice Edge. Physical Review 98, 1865-1866, doi:10.1103/PhysRev.98.1865 (1955).
[39] Savage, K. J. et al. Revealing the quantum regime in tunnelling plasmonics. Nature 491, 574-577, doi:10.1038/nature11653 (2012).
[40] Green, M. A. & Keevers, M. J. Optical properties of intrinsic silicon at 300 K. 3, 189-192, doi:https://doi.org/10.1002/pip.4670030303 (1995).
[41] Jaffe, J. E. & Zunger, A. Theory of the band-gap anomaly in ABC2 chalcopyrite semiconductors. Physical Review B 29, 1882-1906, doi:10.1103/PhysRevB.29.1882 (1984).
[42] Turner, W. J., Reese, W. E. & Pettit, G. D. Exciton Absorption and Emission in InP. Physical Review 136, A 1467-A1470, doi:10.1103/PhysRev.136.A1467 (1964).
[43] Aspnes, D. E. & Studna, A. A. Dielectric functions and optical parameters of Si, Ge, GaP, GaAs, GaSb, InP, InAs, and InSb from 1.5 to 6.0 eV. Physical Review B 27, 985-1009, doi:10.1103/PhysRevB.27.985 (1983).
[44] Kharintsev, S. S. et al. Designing two-dimensional temperature profiles using tunable thermoplasmonics. Nanoscale 14, 12117-12128, doi:10.1039/D2NR03015B (2022).
[45] Agrawal, A. et al. Localized Surface Plasmon Resonance in Semiconductor Nanocrystals. Chemical Reviews 118, 3121-3207, doi:10.1021/acs.chemrev.7b00613 (2018).
[46] Kharintsev, S. S. et al. Light-Controlled Multiphase Structuring of Perovskite Crystal Enabled by Thermoplasmonic Metasurface. ACS Nano, doi:10.1021/acsnano.3c00373 (2023).
[47] Odom, T. W. & Schatz, G. C. Introduction to Plasmonics. Chemical Reviews 111, 3667-3668, doi:10.1021/cr2001349 (2011).
[48] Baffou, G., Cichos, F. & Quidant, R. Applications and challenges of thermoplasmonics. Nature Materials 19, 946-958, doi:10.1038/s41563-020-0740-6 (2020).
[49] Shanks, H. R., Maycock, P. D., Sidles, P. H. & Danielson, G. C. Thermal Conductivity of Silicon from 300 to 1400\ifmmode\hat{ }circ\else\textdegree\fi{ }K. Physical Review 130, 1743-1748, doi:10.1103/PhysRev.130.1743 (1963).
[50] Catchpole, K. R. & Polman, A. Plasmonic solar cells. Opt. Express 16, 21793-21800, doi:10.1364/OE.16.021793 (2008).
[51] Atwater, H. A. & Polman, A. Plasmonics for improved photovoltaic devices. Nature Materials 9, 205-213, doi:10.1038/nmat2629 (2010).
[52] Saive, R. Light trapping in thin silicon solar cells: A review on fundamentals and technologies. 29, 1125-1137, doi:https://doi.org/10.1002/pip.3440 (2021).
[53] G. Baffou, ACS Nano 2021, 15, 5785.
[54] M. Inagaki, T. Isogai, K. Motobayashi, K.-Q. Lin, B. Ren, K. Ikeda, Chem. Sci. 2020, 11, 9807.
[55] B. Fluegel, A. V. Mialitsin, D. A. Beaton, J. L. Reno, A. Mascarenhas, Nat. Commun. 2015, 6, 7136.
[56] E. A. Davis, N. F. Mott, Philos. Mag. 1970, 22, 903.
[57] A. Ibrahim, S. K. J. Al-Ani, Czech. J. Phys. 1994, 44, 785.
[58] W. R. Cai, J. J. Mei, W. Z. Shen, Phys. B. 2004, 352, 179.
[59] S. S. Kharintsev, A. I. Noskov, E. I. Battalova, L. Katrivas, A. B. Kotlyar, J. Merham, E. O. Potma, V. A. Apkarian, D. A. Fishman, (Preprint) arXiv:2304.14521, v2, submitted: April 2023.
[60] V. M. Shalaev, C. Douketis, T. Haslett, T. Stuckless, M. Moskovits, Phys. Rev. B 1996, 53, 11193.
[61] M. R. Beversluis, A. Bouhelier, L. Novotny, Phys. Rev. B 2003, 68, 115433.
[62] N. Rivera, I. Kaminer, B. Zhen, J. D. Joannopoulos, M. Soljačić, Science 2016, 353, 263.
[63] N. F. Mott, E. A. Davis, R. A. Street, Philos. Mag. 1975, 32, 961.
[64] D. A. Drabold, Y. Li, B. Cai, M. Zhang, Phys. Rev. B 2011, 83, 045201.
[65] D. T. Pierce, W. E. Spicer, Phys. Rev. B 1972, 5, 3017.
[66] H. Wada, T. Kamijoh, Jpn. J. Appl. Phys. 1996, 35, L648.
[67] G. K. M. Thutupalli, S. G. Tomlin, J. Phys. C: Solid State Phys. 1977, 10, 467.
[68] M. A. Paesler, D. E. Sayers, R. Tsu, J. Gonzalez-Hernandez, Phys. Rev. B 1983, 28, 4550.
[69] C. Spinella, S. Lombardo, F. Priolo, J. Appl. Phys. 1998, 84, 5383.
[70] H. Kim, G. Park, S. Park, W. Kim, ACS Nano 2021, 15, 2182.
[71] W. Y. Ching, C. C. Lin, D. L. Huber, Phys. Rev. B 1976, 14, 620.
[72] B. Kramer, Phys. State Sol. 1971, 47, 501.
[73] K. Prasai, P. Biswas, D. A. Drabold, Semicond. Sci. Technol. 2016, 31, 073002.
[74] O. Yaffe, Y. Guo, L. Z. Tan, D. A. Egger, T. Hull, C. C. Stoumpos, F. Zheng, T. F. Heinz, L. Kronik, M. G. Kanatzidis, J. S. Owen, A. M. Rappe, M. A. Pimenta, L. E. Brus, Phys. Rev. Lett. 2017, 118, 136001.
[75] C. Oses, C. Toher, S. Curtarolo, Nat. Rev. Mater 2020, 5, 295.
[76] O. V. Rambadey, A. Kumar, K. Kumar, V. Mishra, P. R. Sagdeo, J. Phys. Chem. C 2022, 126, 13946.
[77] O. V. Rambadey, M. Gupta, A. Kumar, P. R. Sagdeo, J. Appl. Phys. 2023, 133, 131101.
[78] H. Fröhlich, Proc. R. Soc. A 1947, 188, 532.
[79] M.-L. Zhang, D. A. Drabold, Eur. Phys. J. B 2010, 77, 7.
[80] N. N. Ovsyuk, V. N. Novikov, Phys. Rev. B 1998, 57, 14615.
[81] Y.-C. Hu, H. Tanaka, Nat. Phys. 2022, 18, 669.
[82] Y. Yamada, Y. Kanemitsu, NPG Asia Mater. 2022, 14, 48.
[83] A. H. Compton, Phys. Rev. 1923, 21, 483.
[84] N. Anderson, A. Bouhelier, L. Novotny. J. Opt. A: Pure Appl. Opt. 2006, 8, S227.
[85] R. Zhang, Y. Zhang, Z. C. Dong, S. Jiang, C. Zhang, L. G. Chen, L. Zhang, Y. Liao, J. Aizpurua, Y. Luo, J. L. Yang, J. G. Hou, Nature 2013, 498, 82.
[86] J. Lee, K. T. Crampton, N. Tallarida, V. A. Apkarian, Nature 2019, 568, 78.

1. A semiconductor device comprising:
an indirect bandgap semiconductor section that includes an indirect bandgap material; and
a plurality of nanostructures that are proximate to a surface of the indirect bandgap semiconductor section, each nanostructure having an equivalent spherical diameter from 0.3 nm to 10 nm such that ultraviolet, visible, near-infrared and mid-infrared light absorption and emission in the indirect bandgap semiconductor section is increased through an expansion of photon-momentum inside and outside of the indirect bandgap semiconductor section as compared to a free photon.

2. A semiconductor device comprising:
an indirect bandgap semiconductor section; and
a plurality of nanostructures within or contacting the indirect bandgap semiconductor section, each nanostructure having an equivalent spherical diameter from 0.3 nm to 10 nm such that ultraviolet, visible, near-infrared and mid-infrared light absorption and emission in the indirect bandgap semiconductor section is increased through a mechanism of photon-electron momentum matching.

3. The semiconductor device of claim 1, wherein the plurality of nanostructures includes structures defined by the surface of the indirect bandgap semiconductor section.

4. The semiconductor device of claim 2, wherein the plurality of nanostructures includes structures defined in a volume of the indirect bandgap semiconductor section.

5. The semiconductor device of claim 1, wherein the indirect bandgap material is silicon.

6. The semiconductor device of claim 1, wherein the indirect bandgap semiconductor section is a heterogeneous cross-linked silicon glass layer and the plurality of nanostructures is a plurality of c-Si nanocrystals embedded in an amorphous silicon matrix, wherein the c-Si nanocrystals have an equivalent spherical diameter such that ultraviolet, visible, near-infrared and mid-infrared light absorption and emission in the heterogeneous cross-linked silicon glass layer is increased through photon-electron momentum matching.

7. The semiconductor device of claim 1, wherein the plurality of nanostructures includes physical structures that are fabricated by chemical etching, focused ion milling, electron beam lithography, photolithography, Bosch milling or machined into the indirect bandgap semiconductor section.

8. The semiconductor device of claim 1, wherein the plurality of nanostructures includes metal nanostructures or semimetal nanostructures.

9. The semiconductor device of claim 1, wherein the plurality of nanostructures includes semiconducting nanostructures.

10. The semiconductor device of claim 1, wherein the plurality of nanostructures is arranged as an array over a surface of the indirect bandgap semiconductor section.

11. The semiconductor device of claim 1 wherein the plurality of nanostructures is a metallic grid contacting the surface of the indirect bandgap semiconductor section.

12. The semiconductor device of claim 2 wherein the plurality of nanostructures is a metallic grid, arrangement, specific design, periodic structure within or contacting the indirect bandgap semiconductor section.

13. The semiconductor device of claim 1 wherein the plurality of nanostructures is a semiconducting grid contacting the surface of the indirect bandgap semiconductor section.

14. The semiconductor device of claim 2 wherein the plurality of nanostructures is a semiconducting grid within the indirect bandgap semiconductor section.

15. The semiconductor device of claim 1, wherein the plurality of nanostructures are defined by a surface roughness of a layer disposed over the indirect bandgap semiconductor section, the surface roughness having a root mean square roughness less than 10 nm.

16. The semiconductor device of claim 15, wherein the root mean square roughness less than about 5 nm.

17. The semiconductor device of claim 16, wherein the root mean square roughness greater than about 0.3 nm.

18. The semiconductor device of claim 1, wherein the equivalent spherical diameter is at most 5 nm.

19. The semiconductor device of claim 1, wherein the equivalent spherical diameter is at most 3 nm.

20. The semiconductor device of claim 1, wherein the equivalent spherical diameter is at least 1 nm.

21. The semiconductor device of claim 1, wherein adjacent nanostructures are separated by a distance of at least an average equivalent spherical diameter of the plurality of nanostructures.

22. The semiconductor device of claim 1, wherein adjacent nanostructures are separated by at least 3 nm.

23. The semiconductor device of claim 1, wherein adjacent nanostructures are separated by at least 0.3 nm.

24. The semiconductor device of claim 1, wherein adjacent nanostructures are separated by at least 5 nm.

25. The semiconductor device of claim 1, wherein the indirect bandgap semiconductor section includes an indirect bandgap semiconductor selected from the group consisting of silicon (Si), germanium (Ge), InGaAsP modifications, gallium arsenide (GaAs), indium phosphide (InP), cadmium sulfide (CdS), cadmium telluride (CdTe), zinc selenide (ZnSe), zinc telluride (ZnTe), indium antimonide (InSb), lead sulfide (PbS), and zinc oxide (ZnO), and combinations thereof.

26. A photodiode including the semiconductor device of claim 1.

27. A photovoltaic cell including the semiconductor device of claim 1.

28. An optical sensor including the semiconductor device of claim 1.

29. An imaging array including the semiconductor device of claim 1.

30. A nano printing device including the semiconductor device of claim 1.

31. A computational metamaterial device including the semiconductor device of claim 1.

32. A nano heater device for single molecule and supramolecular system, polymerase chain reaction including the semiconductor device of claim 1.

33. A catalysis device including the semiconductor device of claim 1.

34. A water desalination device including the semiconductor device of claim 1.

35. An optical data encrypting device including the semiconductor device of claim 1.

36. A semiconductor device comprising:
a heterogeneous cross-linked semiconductor glass layer composed of a plurality of nano-sized inclusions of crystalline phase embedded in an amorphous semiconducting matrix, wherein the nano-sized inclusions have an equivalent spherical diameter such that ultraviolet, visible, near-infrared, and mid-infrared light absorption and emission in the heterogeneous cross-linked semiconductor glass layer is increased through photon momentum expansion.

37. The semiconductor device of claim 36 wherein the heterogeneous cross-linked semiconductor glass layer is composed of a material that represents an intermediate state between amorphous and crystalline phases, characterized by a narrow distribution of structure sizes.

38. The semiconductor device of claim 36, wherein the equivalent spherical diameter is from 0.3 nm to 10 nm.

39. The semiconductor device of claim 36, wherein the equivalent spherical diameter is at most 5 nm.

40. The semiconductor device of claim 36, wherein the equivalent spherical diameter is at most 3 nm.

41. The semiconductor device of claim 36, wherein the equivalent spherical diameter is at least 1 nm.

42. The semiconductor device of claim 36, wherein adjacent nano-sized inclusions are separated by a distance of at least an average equivalent spherical diameter of the plurality of nano-sized inclusions.

43. The semiconductor device of claim 36, wherein the heterogeneous cross-linked semiconductor glass layer is a heterogeneous cross-linked silicon glass layer and the plurality of nano-sized inclusions is a plurality of are c-Si nanocrystals.

44. The semiconductor device of claim 36, wherein adjacent c-Si nanocrystals are separated by at least 3 nm.

45. The semiconductor device of claim 36, wherein adjacent c-Si nanocrystals are separated by at least 5 nm.

46. The semiconductor device of claim 43, wherein the plurality of nano-sized inclusions includes structures defined by a surface of the heterogeneous cross-linked semiconductor glass layer.

47. The semiconductor device of claim 43, wherein the plurality of nano-sized inclusions includes structures defined in a volume of the heterogeneous cross-linked semiconductor glass layer.

48. The semiconductor device of claim 43, wherein the plurality of nano-sized inclusions induce a surface roughness of the heterogeneous cross-linked semiconductor glass layer, the surface roughness having a root mean square roughness less than 10 nm.

49. The semiconductor device of claim 48, wherein the root mean square roughness is less than about 5 nm.

50. The semiconductor device of claim 48, wherein the root mean square roughness is greater than about 0.3 nm.

51. The semiconductor device of claim 48, wherein the heterogeneous cross-linked silicon glass layer is formed by annealing amorphous silicon (a-Si) with a continuous wave (cw) laser.
